(19) United States
(12) Patent Application Publication
(10) Pub. No.: US 2018/0175233 A1
(43) Pub. Date: Jun. 21, 2018

(54) ALIGNMENT MARKERS FOR PRECISION AUTOMATION OF MANUFACTURING SOLAR PANELS AND METHODS OF USE

(71) Applicant: SolarCity Corporation, San Mateo, CA (US)

(72) Inventors: Anand Junuthula Reddy, Fremont, CA (US); Godfrey S. Suarez, Fremont, CA (US)

(21) Appl. No.: 15/387,578

(22) Filed: Dec. 21, 2016

(51) Int. Cl. H01L 31/18; H02S 20/25; H02S 50/10; H01L 31/20; H01L 31/028; H01L 31/02; H01L 31/0224

(52) U.S. Cl. CPC H01L 31/1876; H02S 20/25; H02S 50/10; H01L 31/022433; H01L 31/028; H01L 31/0201; H01L 31/202

(57) ABSTRACT

Systems and methods for manufacturing solar panels are provided herein. Such systems can include an automated shingling module that creates a string of cells by overlapping the strips. The system can include one or more sensors that determines a distance between first and second markers on a back-side of first and second solar cell sections that correspond to an overlap of the sections. One or both of the first and second markers can include features existing on a back-side pattern or can include modifications of a standard back-side pattern, or can include unique markers. The system can utilize feedback from the sensor to optimize overlap during shingling of overlapping strips.

### CROSS-REFERENCES TO RELATED APPLICATIONS

This application is related to U.S. Non-Provisional patent application Ser. No. 14/960,328 (Attorney Docket Number P103-10NUS) entitled “SYSTEM, METHOD, AND APPARATUS FOR PRECISION AUTOMATION OF MANUFACTURING OF SOLAR PANELS,” filed Dec. 4, 2015, which is incorporated herein by reference in its entirety for all purposes.

### FIELD OF THE INVENTION

Embodiments of the invention pertain to methods, systems and apparatus for automated manufacturing of solar panels.

### DEFINITIONS

“Solar cell” or “cell” is a photovoltaic structure capable of converting sunlight into electricity. A cell may have any size and any shape. A solar cell may be created from a variety of materials. A solar cell may be in the form of a silicon wafer having a photovoltaic structure. It may be a glass with a photovoltaic structure that may be formed by one or more thin-film layers. In addition, a solar cell may be a plastic or any other material capable of supporting a photovoltaic structure on its surfaces.

“Solar cell strip” or “strip” is a segment of a solar cell. A solar cell may be divided into a number of strips. A strip may have any shape and any size. The width and height of a strip may the same or different.

“String of shingled cells,” “string of shingled strips,” “shingled string,” or “string” may be formed by electrically and/or physically connecting a number of strips or a number of solar cells. For example, a string may be created by overlapping two or more strips. Two or more strips may be electrically connected in series and/or in parallel.

### BACKGROUND OF THE INVENTION

The negative environmental impact of fossil fuels and their rising cost have resulted in a dire need for cleaner, cheaper alternative energy sources. Among different forms of alternative energy sources, solar power has been favored for its cleanness and wide availability.

A solar cell converts light into electricity using the photovoltaic effect. There are several basic solar cell structures, including a single p-n junction, p-i-n/n-i-p, and multi-junction. A typical single p-n junction structure includes a p-type doped layer and an n-type doped layer. Solar cells with a single p-n junction can be homojunction solar cells or heterojunction solar cells. If both the p-doped and n-doped layers are made of similar materials (materials with equal band gaps), the solar cell is called a homojunction solar cell. In contrast, a heterojunction solar cell includes at least two layers of materials of different bandgaps. A p-i-n/n-i-p structure includes a p-type doped layer, an n-type doped layer, and an intrinsic (undoped) semiconductor layer (the i-layer) sandwiched between the p-layer and the n-layer. A multi junction structure includes multiple single-junction structures of different bandgaps stacked on top of one another.

In a solar cell, light is absorbed near the p-n junction generating carriers. The carriers diffuse into the p-n junction and are separated by the built-in electric field, thus producing an electrical current across the device and external circuitry. An important metric in determining a solar cell's quality is its energy-conversion efficiency, which is defined as the ratio between power converted (from absorbed light to electrical energy) and power collected when the solar cell is connected to an electrical circuit. High efficiency solar cells are essential in reducing cost to produce solar energies.

In practice, multiple individual solar cells are interconnected, assembled, and packaged together to form a solar panel, which can be mounted onto a supporting structure. Multiple solar panels can then be linked together to form a solar system that generates solar power. Depending on its scale, such a solar system can be a residential roof-top system, a commercial roof-top system, or a ground-mount utility-scale system. Note that, in such systems, in addition to the energy conversion efficiency of each individual cell, the ways cells are electrically interconnected within a solar panel also determine the total amount of energy that can be extracted from each panel. Due to the serial internal resistance resulting from the inter-cell connections, an external load can only extract a limited percentage of the total power generated by a solar panel.

Continuous strings of solar cells that form a solar panel exist. Each string includes several solar cells that overlap one another. This overlapping technique is referred to as “shingling.” U.S. patent application Ser. No. 14/510,008, filed Oct. 8, 2014 and entitled “Module Fabrication of Solar Cells with Low Resistivity Electrodes,” describes several technical advantages that result from shingled cells.

Manufacturing a shingled panel can involve connecting two solar cells by overlapping the cells so that the metal layers on each side of the overlapped cells establish an electrical connection. This process is repeated for a number of successive cells until one string of shingled cells is created. A number of strings are then connected to each other and placed in a frame. One form of shingled panel, as described in the above-noted patent application, includes a series of solar cell strips created by dividing solar cells into smaller pieces (i.e. the strips). These smaller strips are then shingled to form a string.

One problem that arises in manufacturing such shingled panels is that the assembly of shingled strings of solar cells requires precise alignment of the cells to ensure proper electrical connection. Given the level of precision needed to create a shingled string, it is not feasible to manufacture such solar panels in volume manually. There is a need for systems and methods that allow for more consistent and improved alignment of shingled panels during assembly of shingled strings of solar cells, and in particular such systems and methods that are suitable for use in an automated process.

### BRIEF SUMMARY OF THE INVENTION

Embodiments of the invention are directed to systems and methods for precision automation of shingled panels by utilizing automated electro-mechanical systems that act in concert to manufacture and assemble shingled solar panels.

System, apparatus and methods for precision automated assembly and manufacturing of solar panels are provided. Solar cells can have more than one metal layer on each side. The metal layers can collect electrons and holes that result from the photovoltaic reaction that occurs when the sun light is absorbed by the photovoltaic structure of a cell. Each side of the solar cell can include metal layers that are wider than the others. These wider metal layers are sometimes called “busbars” while the smaller metal layers are often referred to as “fingers.” The metal layers can be arranged in a manner such that when a solar cell is divided into two or more smaller solar cell strips, each smaller strip has at least one busbar and a number of fingers to harvest the generated electricity by the solar cell. Additionally, at least one side of a strip can have a busbar that runs substantially along the length of the strip. The other side of the strip can also have a busbar that runs substantially along the length of the strip, but at the opposite end of the busbar on the first side. The strips are overlapped and shingled together such that one busbar of one strip can be electrically and physically connected to a busbar on another strip. Precise alignment of adjacent strips during shingling is facilitated by use of one or more markers defined in a backside of the respective strips. Typically, such markers includes a first marker along one edge that can be identified and the proximity of which can be determined relative a second marker in an adjacent strip so as to ensure overlap of adjacent strips falls within a desired optimum range. This process can be repeated multiple times to form a string of shingled strips.

In one aspect, the invention relates to a photovoltaic structure with a first marker for alignment of the structure with adjacent structures within a cascade or string of structures. The first marker can be defined in a backside of the structure so as to allow alignment from an underside during assembly and to avoid occupying space on a front solar energy receiving surface of the photovoltaic structure. In some embodiments, the photovoltaic structures includes a base layer, a first and second quantum tunneling barrier (QTB) layer deposited on both surfaces of the base layer, an amorphous silicon emitter layer, an amorphous silicon surface field layer, and at least one metallic grid on a back-side of the photovoltaic structure. The first marker can be defined as a portion of the metallic grid and is positioned to facilitate alignment of the photovoltaic structure with an adjacent overlapping photovoltaic structure during assembly of a photovoltaic string. Typically, the first marker is defined so as to be readily identifiable by a user and/or a sensor in an automated process. Such a sensor can be an optical or photo-sensor, a proximity sensor, and the like.

In some embodiments, the first marker is a unique mark or symbol. In other embodiments, the first marker is a modification of a standard pattern of the metallic grid, such as an extended portion of the busbar of the grid or a portion of the grid. In some embodiments, the first marker is disposed within the grid pattern so as to be adjacent a second marker in an adjacent along a direction of overlap. The second marker can be a unique feature, a modification of an existing backside pattern, or an existing backside feature, such as a contact pad. In some embodiments, the second marker can be the first marker of the adjacent section.

In another aspect, the photovoltaic structure adapted for improved alignment includes a front side having a solar energy receiving surface, a back side having a metal grid for harvesting electrical energy from the photovoltaic structure upon receiving solar energy on the front side, and a first marker disposed on the back side to facilitate alignment of the photovoltaic structure with an adjacent overlapping photovoltaic structure during assembly of a photovoltaic string. As described in various embodiments, the first marker can be defined within the metal grid pattern. The first marker can be a unique feature, a modification of a standard or existing pattern, or an existing backside feature. In some embodiments, the first marker is within the grid pattern so as to be adjacent and aligned a second marker in the adjacent photovoltaic structure within the photovoltaic string along a direction of overlap.

In another aspect, the invention pertains to a system for forming a photovoltaic string having overlapping photovoltaic sections. Such systems can include a shingling module for positioning multiple photovoltaic structures relative each other and a sensor unit adapted and positioned to determine a degree of overlap between adjacent photovoltaic sections. The shingling module includes multiple support elements adapted to support each of the photovoltaic structures. The first and second markers and sensor unit can be as described in any of the embodiments described herein.

In some embodiments, the system includes a control unit operatively coupled with at least some of the support elements supporting the photovoltaic sections during shingling and the sensor unit. The control unit can be configured to adjust a position of the photovoltaic structures via movement of the support elements in response to a determination of the degree of overlap. Typically, the control unit obtains a distance between the first and second markers in adjacent photovoltaic structures from which the degree of overlap is determined.

In another aspect, methods for aligning a multiple photovoltaic structures within a photovoltaic string are provided. Such methods can include supporting multiple photovoltaic structures such that the structures are independently positionable relative each other. Each of the photovoltaic structures has a front side adapted for receiving solar energy and a back side having a metal grid for harvesting electrical energy produced by the photovoltaic structure. The photovoltaic structures are then positioned so that at least a first photovoltaic structure has an overlap with a second photovoltaic structure. The first marker of the first structure is then detected. Next, it is determined whether an overlap between the first photovoltaic structure and the adjacent second photovoltaic structure is within a desired range based on a position of the first marker relative a position of a second marker in the second photovoltaic structure. The first and second markers and sensor unit can be defined according to any of the embodiments described herein. In some embodiments, determining whether the overlap is within the desired range includes determining a distance between the first marker and the second marker. Such methods can further include repositioning at least one of the photovoltaic structures in response to a determination that the overlap is outside of the desired range.

It will be understood by those skilled in the art that the order of the above processes may vary, and one or more of processes may be eliminated as appropriate.

### BRIEF DESCRIPTION OF THE DRAWINGS

FIG. 1A shows a string of solar cells assembled in accordance with some embodiments of the invention.

FIG. 1B shows overlapping portions of solar cells assembled in accordance with some embodiments.

FIG. 1C shows overlapping portions of solar cells assembled in accordance with some embodiments.

FIG. 1D shows a front side of a solar cell in accordance with some embodiments.

FIG. 1E shows a back side of a solar cell in accordance with some embodiments.

FIGS. 1F-1G show front and back sides, respectively, of a solar cell section for assembling in a string in accordance with some embodiments.

FIG. 2A shows formation of shingled solar panel in accordance with some embodiments.

FIG. 2B shows formation of shingled solar panel in accordance with some embodiments.

FIG. 2C shows a solar cell in accordance with some embodiments.

FIG. 2D shows a solar cell, in accordance with some embodiments.

FIG. 3 shows formation of shingled solar panel in accordance with some embodiments.

FIG. 4A shows a flowchart depicting a precision automated assembly process for solar panels in accordance with some embodiments.

FIG. 4B shows a flowchart depicting a precision automated assembly process for solar panels in accordance with some embodiments.

FIGS. 5A-5D shows an exemplary solar cell and marker configurations in accordance with some embodiments.

FIG. 6 shows placement of solar cells on a conveyor in accordance with some embodiments.

FIG. 7 shows placement of solar cells on a conveyor in accordance with some embodiments.

FIG. 8 shows laser scribing solar cells in accordance with some embodiments.

FIG. 9 shows laser scribing solar cells in accordance with some embodiments.

FIG. 10 shows applying conductive paste on solar cells in accordance with some embodiments.

FIG. 11 shows applying conductive paste on solar cells in accordance with some embodiments.

FIG. 12A shows a laser scribed solar cell in accordance with some embodiments.

FIG. 12B shows dividing a solar cell into smaller solar cells in accordance with some embodiments.

FIG. 12C shows divided smaller collar cells in accordance with some embodiments.

FIG. 13 shows a robotic arm for lifting solar cells in accordance with some embodiments.

FIG. 14 shows an apparatus for dividing solar cells into smaller strips in accordance with some embodiments.

FIGS. 15A-15B shows an apparatus for dividing solar cells into smaller strips in accordance with some embodiments.

FIGS. 16A-16B show lifting solar cells to form a shingled assembly in accordance with some embodiments.

FIG. 17A shows a shingling module for assembly of shingled strings of solar cells in accordance with some embodiments.

FIG. 17B shows a shingling module for assembly of shingled strings of solar cells in accordance with some embodiments.

FIG. 17C shows a shingling module for assembly of shingled strings of solar cells in accordance with some embodiments.

FIG. 17D shows a shingling module for assembly of shingled strings of solar cells in accordance with some embodiments.

FIG. 17E shows a shingling module for assembly of shingled strings of solar cells in accordance with some embodiments.

FIG. 18 shows two strings of shingled solar cells in accordance with some embodiments.

FIG. 19 shows one string of shingled solar cells in accordance with some embodiments.

FIG. 20A shows alignment of solar cells prior to shingling in accordance with some embodiments.

FIG. 20B shows one string of shingled solar cells in accordance with some embodiments.

FIGS. 21A and 21B show an annealing process in accordance with some embodiments.

FIG. 22 shows a targeted annealing module in accordance with some embodiments.

FIG. 23 shows a precision automation system for assembly of shingled solar cells and a layup tool for placement of strings of shingled solar cells on a backsheet in accordance with some embodiments.

FIG. 24 shows a control system that can facilitate assembly of a solar panel in accordance with some embodiments.

### DETAILED DESCRIPTION OF THE INVENTION

The following description is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the disclosure. Thus, the invention is not limited to the embodiments described and shown.

Embodiments of the invention provide methods, systems and apparatus for precision automated assembly and manufacturing of shingled solar panels. During fabrication, conventional solar cells including multi-layer semiconductor structures may first be fabricated using conventional silicon wafers. In one aspect, the solar cells are fabricated in sections, each section having a busbar near an edge on opposite edge on opposing sides. Each solar cell can be cleaved to separate each section, which is then shingled such that a front-side busbar of one section contacts a back-side busbar of an adjacent section. Such a shingled configuration forms a cascaded string of solar panels that maximizes the solar energy receiving surface. In forming such a cascaded string of solar cells, it is desirable to provide a precise amount of overlap between adjacent shingled sections during the assembly process. In some embodiments, the solar cells are formed with back-side features that include first and second markers such that a distance between a first marker in one solar section and a second marker in an adjacent solar section corresponds to an amount of overlap. The first marker can be a unique feature or a modification of a standard feature (e.g. grid pattern) so as to be readily identifiable by the user and/or a sensor of an automated system. In some embodiments, the first feature is a portion of the metal grid included on the back-side of the solar cell section. The distance can be measured manually by personnel during the assembly process or can be automated, such that it can be performed periodically or substantially continuously during assembly. The alignment of the sections can be adjusted in response to the measured distance to provide an optimal overlap within a desired range.

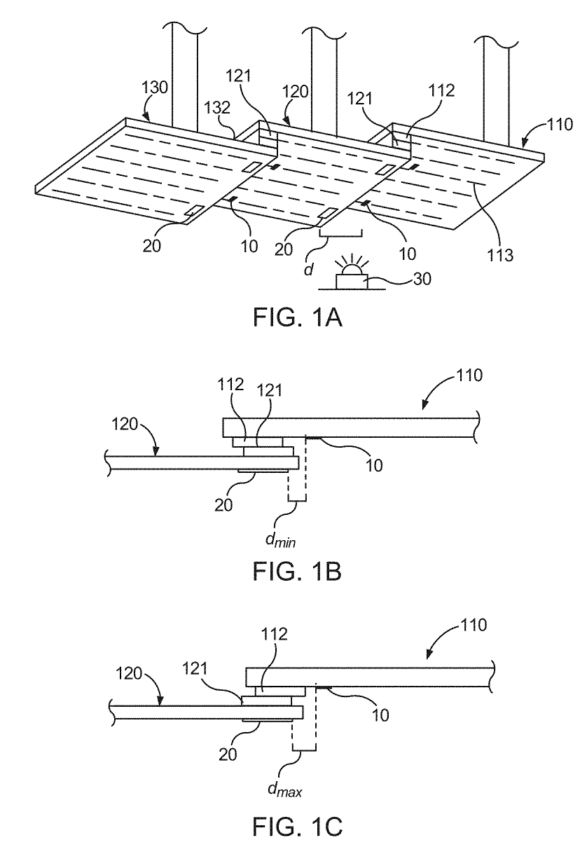

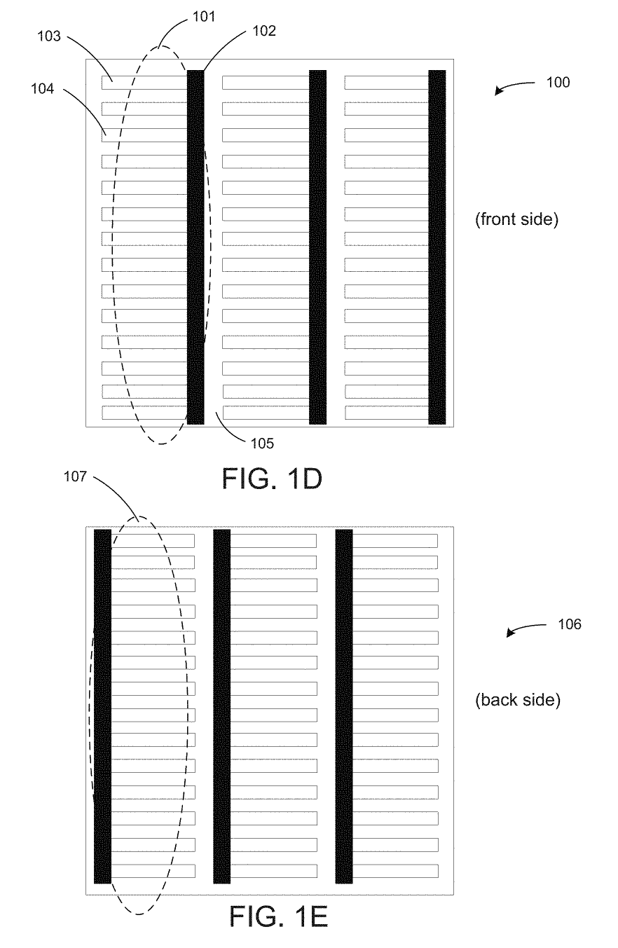

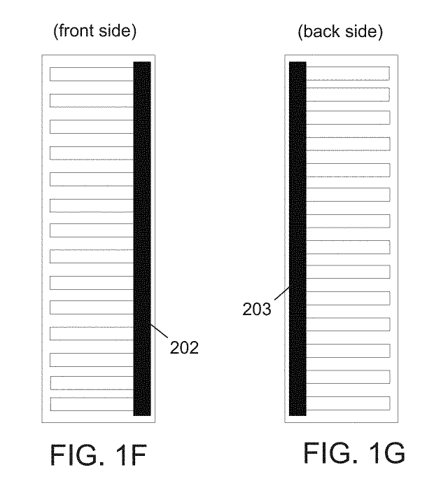

As shown in FIG. 1A, a solar cell has been cleaved into sections 110, 120 130 which are then supported by support members and positioned to overlap so that back-side busbars 121, 132 contact front-side busbars 112, 121. The back-side of each section is exposed to a sensor 30 which determines whether the overlap is within a desired overlap range. While in this embodiment, the desired overlap is typically within a range of 1 mm to 3 mm, preferably about 2 mm. It is appreciated, however, that the desired overlap depends on the particular configuration of each section in the string such that various other embodiments realized could utilize different degrees of overlap. In some embodiments, the system determines the degree of overlap by measuring a distance (d) between first marker 10 in one section and second marker 20 in an adjacent panel. Second marker 20 can be a unique feature, a modification of an existing pattern or an existing feature, such as a contact pad, as shown in FIG. 1A. It is further appreciated that the second marker 20 could be the first marker 10 of the adjacent section.

In some embodiments of the system, the desired overlap of the second solar cell section with the first solar cell is within a range of 0.5 mm to 10 mm, typically between 1 mm to 5 mm, more typically, about two millimeters. It is understood that the distance between markers depends on the placement of the first and second markers on the respective solar cell sections.

As can be seen in FIGS. 1B and 1C, the distance between first marker 10 and second maker 20 in overlapping sections 110 and 120 corresponds to the overlap distance, thereby allowing the user or an automated system to readily determine the degree of overlap from the back-side of the assembly. In some embodiments, adjacent sections can be adjusted to maintain the distance within a desired range so as to ensure a proper connection between bus-bars yet avoid excessive overlap which would cover or shade a portion of the solar receiving surface of the overlapped section. For example, FIG. 1B depicts a minimum distance (dₘᵢₙ) that corresponds to a maximum desired overlap. Any smaller distance would cause an unacceptable overlap of section 110 over 120 such that section 110 begins to cover the solar energy receiving surface. FIG. 1C depicts a maximum distance that corresponds to a minimum overlap to ensure proper contact between busbars. If the distance were any greater, the contact area between busbars could be less than desired during the annealing process and the integrity of the connection could become compromised over time.

In some embodiments, the measurement of distance between markers can be performed periodically such as in a quality control check. In some embodiments, measurement of the distance between markers can be performed substantially continuously during assembly to allow for real-time adjustment of the sections during assembly to ensure optimal overlap.

In one aspect, one or both of the first and second markers can be a standard feature in an existing back-side design of the solar cell. For example, the second marker in the configuration in FIG. 1A can be a contact pad in the back side design near an overlapped edge of the respective section. In another aspect, the first or second marker can be defined as a unique feature (e.g. dot, symbol, protrusion) or any modification of a standard pattern (e.g. metal grid pattern) that could be readily identifiable by the user and/or an automated system.

In some embodiments, the multi-layer semiconductor structure is a double-sided tunneling heterojunction solar cell. The solar cells can have a standard size, such as the standard 5-inch or 6-inch squares. The solar cells can be 6×6 inch square-shaped cells. Subsequently, front- and back-side metal grids may be deposited on the front and back surfaces of the solar cells respectively to complete the bifacial solar cell fabrication, such as in FIGS. 1D and 1E.

In some embodiments, depositing of front- or back-side metal grids may include electroplating of a Cu grid, which may be subsequently coated with Ag or Sn. In other embodiments, one or more seed metal layers, such as a seed Cu or Ni layer, can be deposited onto the multi-layer structures using a physical vapor deposition (PVD) technique to improve adhesion and ohmic contact quality of the electroplated Cu layer. Different types of metal grids can be formed, including, but not limited to: a metal grid with a single busbar at the center and a metal grid with a single busbar at the cell edge. In the “edge-busbar” configuration, the busbars at the front and back surfaces of the solar cells may be placed at opposite edges, respectively. Because standard 5- or 6-inch solar cells may be divided into smaller strips, which can involve a scribe-and-cleave process, special patterns for the metal grid may be used. First, the metal grid layout allows a conventional cell to be divided into multiple smaller strips. Second, due to the malleability of the Cu grid, it can be difficult to cleave a wafer across the Cu grid lines. Therefore, as illustrated in FIGS. 1D and 1E, when depositing the metal grid, blank spaces can be reserved to facilitate the subsequent cell-dividing process.

FIG. 1D shows an exemplary metal grid pattern on the front surface of a solar cell, according to one embodiment. Metal grid 100 includes three sub-grids, such as sub-grid 101. Each sub-grid may be designed to be the front-side grid for the strip of cell. Hence, the three sub-grid configuration allows the solar cell to be divided into three strips of cells. Various types of metal grid patterns can be used for each sub-grid, such as a conventional grid pattern with double busbars, a single center-busbar grid pattern, or a single edge-busbar grid pattern. In the example shown, the sub-grids have a single edge-busbar pattern. In the FIGS. 1D-1E, each sub-grid includes an edge-busbar running along the longer edge of corresponding strip of cell and a number of parallel finger lines running in a direction parallel to the shorter edge of the solar cell strip. For example, sub-grid 101 includes an edge-busbar 102, and a number of finger lines, such as finger lines 103 and 104. To facilitate a subsequent laser-based scribe-and-cleave process, a predefined blank space (with no metal deposition) is placed between the adjacent sub-grids. For example, blank space 105 may be defined to separate sub-grid 101 from its adjacent sub-grid. In some embodiments, the width of the blank space, such as blank space 105, can be between 0.5 mm and 2 mm. There is a tradeoff between a wider space that leads to an easier scribing operation and a narrower space that leads to more effective current collection. In one embodiment, the width of such a blank space may be 1 mm.

FIG. 1E shows an exemplary metal grid pattern on the back surface of a solar cell. In the example shown in FIG. 1E, back metal grid 106 includes three sub-grids, such as sub grid 107. For the strips of cells to be bifacial, the back-side sub-grid may correspond to the front side sub-grid. In this example, the front side of the cell includes three sub-grids, and each sub-grid has a single edge-busbar. In the embodiment shown in FIGS. 1D and 1E, the front and back-side sub-grids have similar patterns except that the front and back edge-busbars are located adjacent to opposite edges of the strip of cell. In other words, in the example shown in FIGS. 1D and 1E, the busbar on the front side of the strip is located at one edge of the front surface, and the busbar on the back side is located at the opposite edge of the back surface. In addition, the locations of the blank spaces in back metal grid 106 correspond to locations of the blank spaces in front metal grid 100, such that the Cu grid lines do not interfere with the subsequent wafer-cutting process.

Subsequent to depositing the front and back metal grid, each solar cell is divided into multiple smaller cells. Various techniques can be used to divide the cells. In some embodiments, a laser-based scribe-and-cleave technique is used. More specifically, a high-power laser beam may be used to scribe the surface of the solar cell at the desired locations (such as blank space 105) to a pre-determined depth, followed by applying appropriate force to cleave the scribed solar cell into multiple smaller cells. In order to prevent damage to the emitter junction, laser scribing can be performed on the surface corresponding to the surface field layer. FIG. 1F shows the front side of a strip or section (region 101 in FIG. 1D) obtained after cleaving cell 100. FIG. 1G shows the back-side corresponding to region 107 in FIG. 1E. As shown, the front side of the strip in FIG. 1F includes edge busbar 202 and the back side of the strip in FIG. 1G includes edge busbar 203, which can be interfaced when the strips are overlapped within a cascaded string.

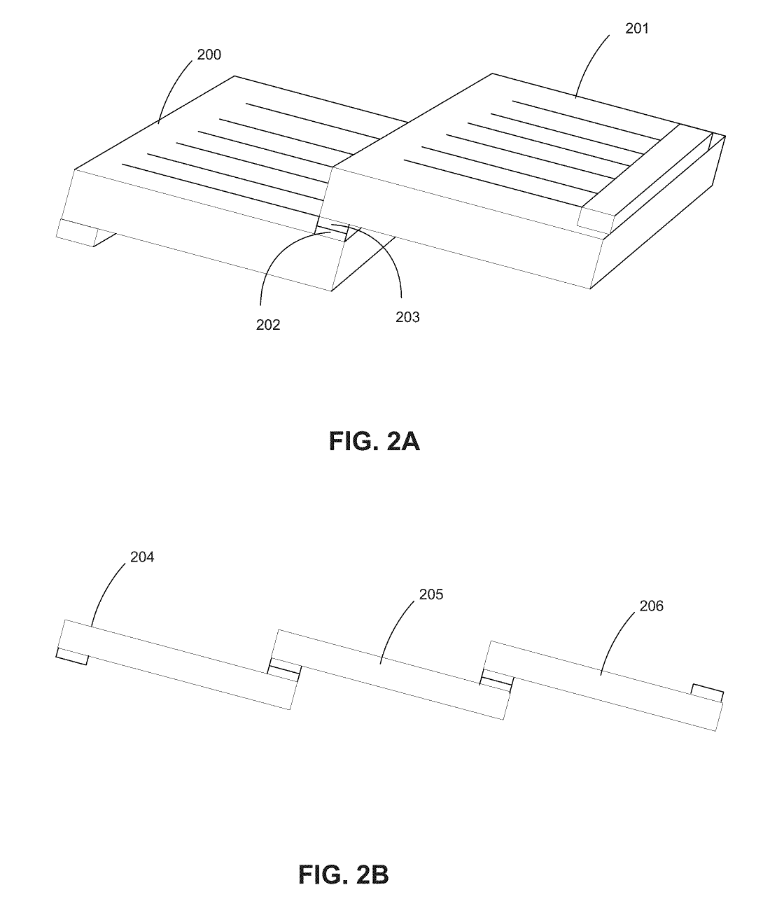

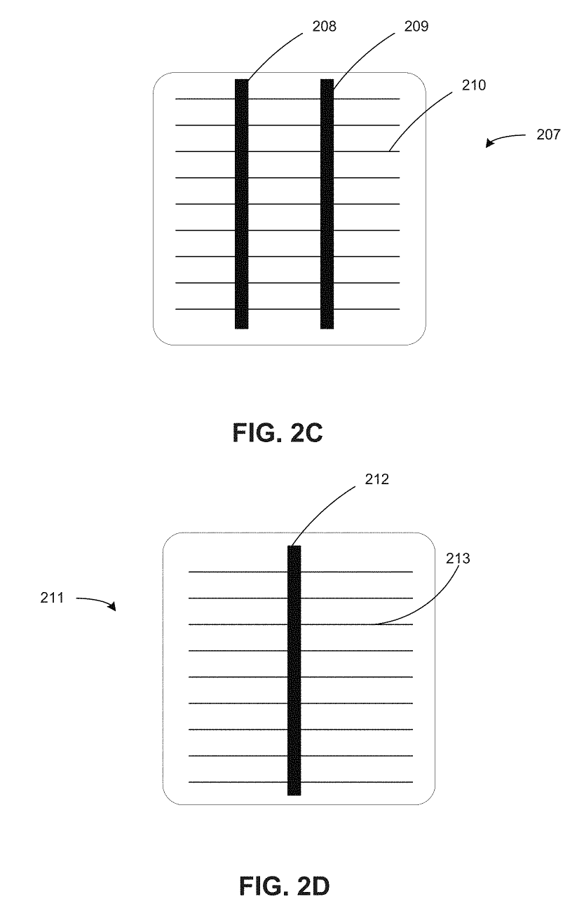

After the formation of smaller cells, a number of the smaller cells can be connected together in series to form a solar cell string. In some embodiments, two rows of smaller cells with each row including 32 smaller cells are connected in series to form a U-shaped string. In some embodiments, depending on the busbar configuration, the conventional stringing process may be modified. For the single edge-busbar configuration as shown in FIGS. 2A and 2B, each solar cell can be rotated 90 degrees, and a single tab that is as long as the long edge of the smaller cell and is between 3 and 12 mm in width can be used to connect two adjacent smaller cells. In some embodiments, the width of the single tab is between 3 and 5 mm. Detailed descriptions of connecting two adjacent smaller cells using a single tab can be found in U.S. patent application Ser. No. 14/153,608 (Attorney Docket No. SSP13-1001US), entitled “MODULE FABRICATION OF SOLAR CELLS WITH LOW RESISTIVITY ELECTRODES,” filed Jan. 13, 2014, the disclosure of which is incorporated by reference in its entirety herein.

FIG. 2A shows a series of solar cells arranged that form a “shingled” pattern. FIG. 2A shows a serial connection between two adjacent smaller cells with a single edge-busbar per surface. In FIG. 2A, the strip of solar cell 200 and the strip of solar cell 201 are coupled to each other via edge-busbar 202 located at the top surface of the solar cell strip 200, and an edge-busbar 203 located at the bottom surface of the solar cell strip 201. More specifically, in one embodiment, the bottom surface of the strip 201 partially overlaps with the top surface of the strip 200 at the edge in such a way that bottom edge-busbar 203 is placed on top of and in electrical contact with top edge-busbar 202. The markers described herein allow for improved determination and control over the degree of overlap between adjacent solar cell strip sections.

In some embodiments, the edge-busbars that are in contact with each other are soldered together to enable the serial electrical connection between adjacent solar cell strips. In further embodiments, the soldering may happen concurrently with a lamination process, during which the edge-overlapped solar cell strips are placed in between a front-side cover and a back-side cover along with appropriate sealant material. The sealant material can include adhesive polymer, such as ethylene vinyl acetate (EVA). During lamination, heat and pressure are applied to cure the sealant, sealing the solar cells between the front-side and back-side covers. The same heat and pressure can result in the edge-busbars that are in contact, such as edge-busbars 202 and 203, being soldered together. In some embodiments, the pressure applied during the lamination process can be above 1.0 atmospheres, for example 1.2 atmospheres. In some embodiments, the edge-busbars are connected via a conductive paste. When the paste is applied to a metal layer such as the busbar, the metallic core establishes an electrical connection with the metal layer while the resin that surrounds the metallic core functions as an adhesive. The resin can include a number of conductive particles such as Ag. The conductive particles may be coated with a protection layer that evaporates when the paste is thermally cured and thereby result in electrical conductivity between the conductive particles that are suspended inside the resin.

FIG. 2B shows the side-view of a string of shingled strips. In FIG. 2B, strip 204 partially overlaps adjacent strip 205, which also partially overlaps (on its opposite end) cell 206. Such a string forms a pattern that is similar to roof shingles. In some embodiments, the three strips shown in FIG. 2B are part of a standard 6-inch square or a pseudo-square solar cell, with each strip of solar cell having a dimension of 2 inches by 6 inches. Compared with an undivided 6-inch solar cell, the partially overlapped strips provide roughly the same photo-generation area, but can lead to less power being consumed by the series resistance due to reduced current.

In one aspect, it is desirable to keep overlapping to a minimum to minimize shading that may be caused by the overlapping and maximize the surface area that will be exposed to sun light. In some embodiments, the single busbars (both at the top and the bottom surface) is placed at the very edge of the strip (as shown in FIG. 2B), thus minimizing the overlapping. To ensure that strips in two adjacent strings are connected in series, the two adjacent strings may have opposite shingle patterns. Moreover, a wide metal tab can be used to serially connect the end strips at the two adjacent strings. Detailed descriptions of serially connecting solar cells in a shingled pattern can be found in U.S. patent application Ser. No. 14/510,008, filed on Oct. 8, 2014 and entitled “Module Fabrication of Solar Cells with Low Resistivity Electrodes,” the disclosure of which is incorporated herein by reference in its entirety.

Solar cells may have a variety of metal grid pattern. FIGS. 2C and 2D show two exemplary solar cells with different metal grids. FIG. 2C shows solar cell 207 having two busbars 208 and 209 and a number of fingers 210. As shown in FIG. 2C, busbars are parallel with respect to each other and substantially run along the length of the solar cell. FIG. 2D shows solar cell 211 having one busbar 212 and a number of fingers 213. As shown in FIG. 2D busbar 212 is in the middle of the solar cell 211. However, the busbar may be located at any location on the surface of the cell and in any orientation.

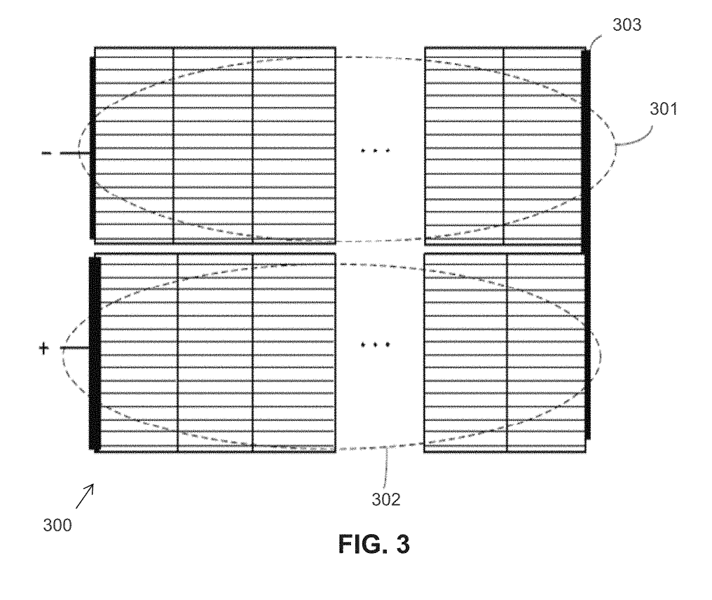

FIG. 3 shows the top view of an exemplary string of shingled cells that includes two strings, according to one embodiment. In FIG. 3, string 300 includes two sub-strings, top string 301 and bottom string 302. Each string includes a number of strips of cells arranged in a shingled pattern. The serial connection is made by the overlapping the busbars at the edge of each strip. As a result, when viewing from the top, no busbar is visible on each strip. In FIG. 3, metal tab 303 couples the top edge-busbar of the strip at the end of string 301 to the bottom busbar at the end of the string 302. At the left end of the strings, lead wires can be soldered onto the top and bottom edge busbars of the end smaller cells, forming the output electrode of string 300 to enable electrical connections between string 302 and other strings. Subsequent to formation of multiple strings, the multiple strings are laid out next to each other to form a panel. In some embodiments, three U-shaped strings are laid out next to each other to form a panel that includes 6 strings of strips of cells. After laying out the strings, the front-side cover is applied. In some embodiments, the front-side cover may include a layer of glass.

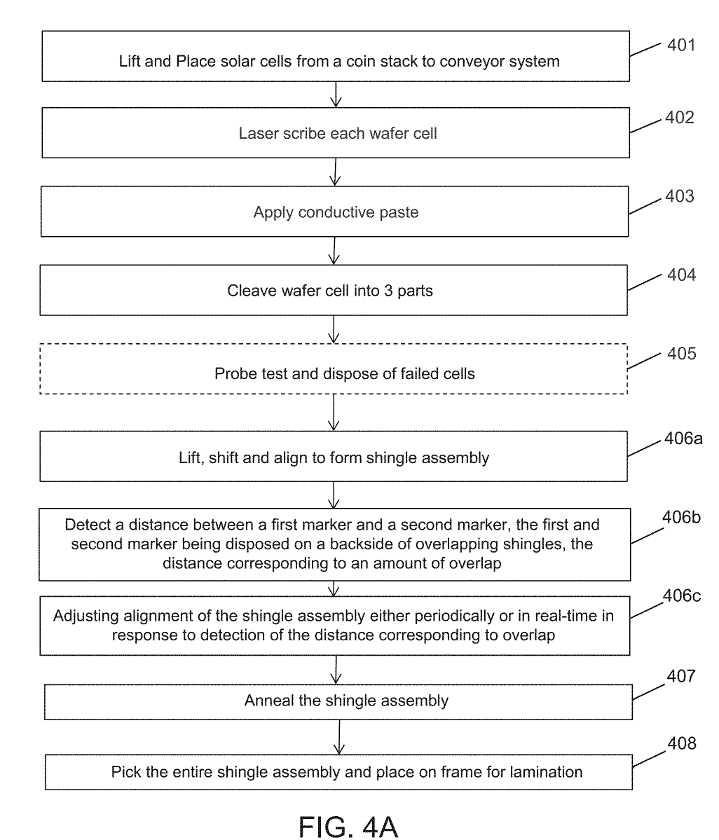

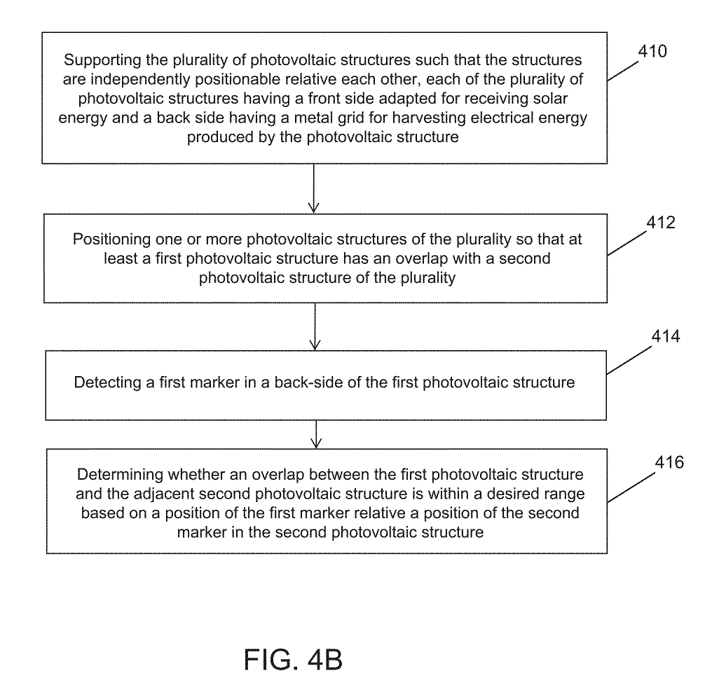

The automated processes, methods, systems and apparatus for assembly of the “shingled” solar panel that was described above is further described according to certain embodiments. FIG. 4A shows a flowchart that describes the steps involved in the automated process for assembly of the shingled solar panel. It will be understood by those skilled in the art that the order of the steps may be switched and/or some of the steps may be combined. The flowchart of FIG. 4A is one example of the automated assembly process and is not intended to be limiting. Furthermore, the specific operation(s) described within each of the steps may be changed with other operations that achieve similar result. For example, the laser scribing in step 402 that divides the cells may instead be replaced by temperature differential operation described above. Thus, it will be understood by those skilled in the art that various other operation(s) disclosed in this application may be used instead of those shown in FIG. 4A. The process will now be described with reference to FIG. 4A and other corresponding figures that show each of the steps in FIG. 4A.

FIG. 4B shows a simplified flowchart of an assembly method utilizing alignment markers as described herein. Such an assembly method includes a step 410 of supporting multiple photovoltaic structures such that the structures are independently positionable relative each other, each of the photovoltaic structures having a front side adapted for receiving solar energy and a back side having a metal grid for harvesting electrical energy produced by the photovoltaic structure. Step 412 includes positioning one or more photovoltaic structures so that at least a first photovoltaic structure has an overlap with a second photovoltaic structure. Step 414 includes detecting a first marker in a back-side of a first photovoltaic structure. Typically, the first marker is an optical feature, either a unique marking or a modification of an existing optically detectable pattern. Detection can be performed by the user or by a sensing unit configured to identify and detect a position of one or more markers. Step 416 includes determining whether an overlap between the first photovoltaic structure and an adjacent second photovoltaic structure is within a desired range based on a position of the first marker relative a position of a second marker in the second photovoltaic structure. Typically, this determination is performed by measuring a distance between markers or between the first marker and a feature of the adjacent section or strip, as described herein.

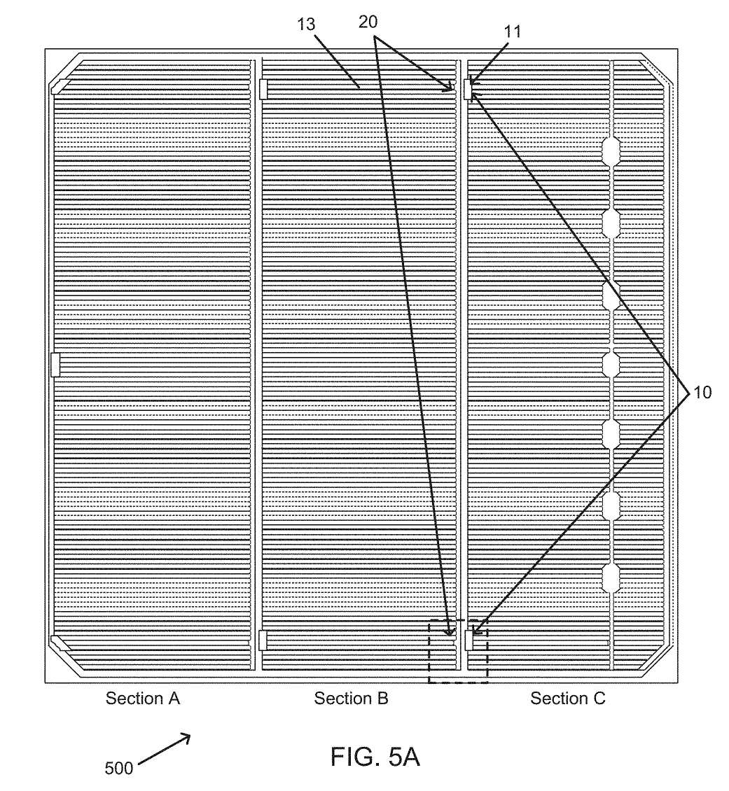

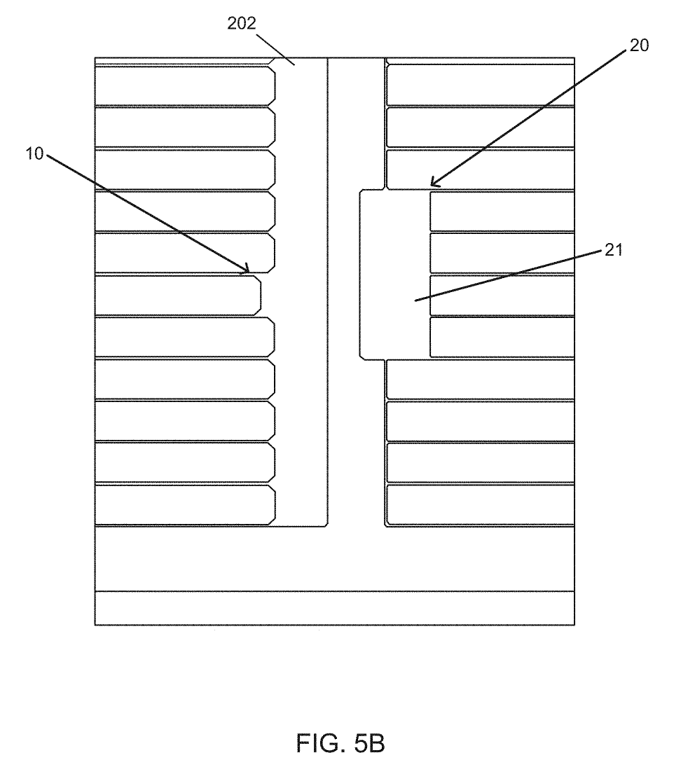

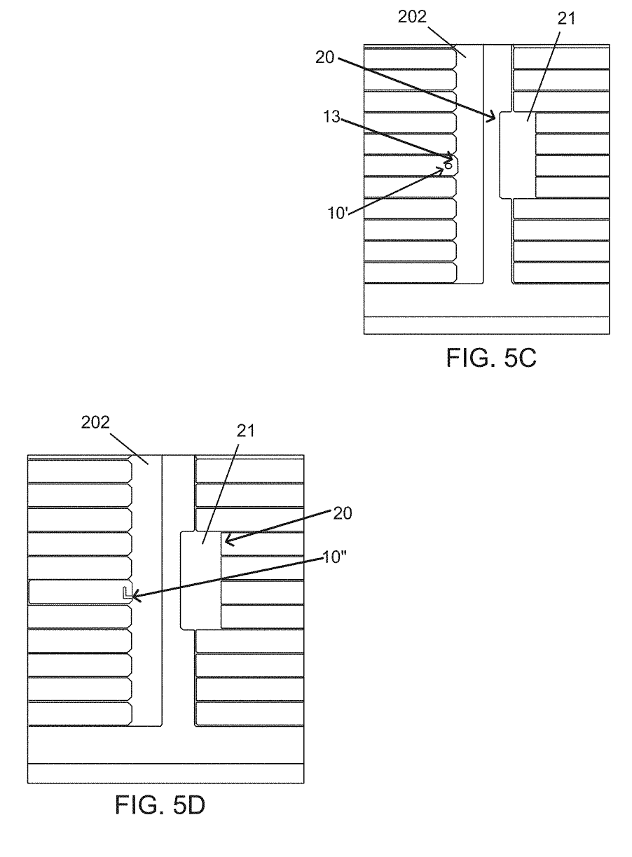

FIG. 5A shows exemplary solar cell 500, which may be similar to the solar cell described in FIGS. 1D and 1E. In some embodiments, the solar cell is square, for example, an exemplary solar cell can be 156 mm×156 mm. In some embodiments, the final panel that results from using solar cells of FIG. 5 may be 1702 mm×980 mm and the shingle cell layout of such a panel may be 1668 mm by 946 mm. It is appreciated that various other dimensions can be realized. In one embodiment, dimensions of a panel may be dependent upon the size of the solar cell from which the strips are extracted, and the amount of desired power that a panel should generate.

In this embodiment, solar cell 500 is laid out in three sections, Section A, B and C, so that each section can be cleaved and separated in a subsequent step. One or more of the sections include a first marker 10 disposed near each end of the edge that will overlap the edge of an adjacent solar cell strip section (see middle section B in FIG. 5A). In this embodiment, the second marker 20 is an existing feature, a contact pad of the metal grid 13. FIG. 5B shows a detail view of first and second markers in FIG. 5A. As can be seen, marker 10 is a modification of an existing grid pattern, namely an elongated portion of edge busbar 202, which is aligned in a direction of overlap with second marker 20, an edge of contact pad 21, such that a distance measured between first and second markers in a direction of overlap corresponds to the degree of overlap. FIGS. 5C and 5D depict alternative configurations of first marker 10. In FIG. 5C, first marker 10′ is an additional feature between two adjacent fingers of the metallic grid, such as a circle, oval or any shape desired. Such a feature can be formed by modification of a mask used in defining the metallic grid and busbars during fabrication of the cell or can be deposited or formed by any suitable means during or after formation of the metallic grid. In FIG. 5D, first marker 10′ is a feature that extends away from the busbar between adjacent fingers within the metallic grid. The feature can be defined so that a distance between the first marker and the second marker can be readily determined or measured. For example, in this embodiment, the feature includes a distal portion that extends parallel to the edge of the contact pad (i.e. second marker) of the adjacent, overlapped shingled strip. Each of the above features are readily identifiable by a user or by an automated sensor to allow for determination of the degree of overlap.

While each of the first and second markers are described generally as visually recognizable or contrast features that can be optically identified by the user or an optical or photo-type sensor, it is appreciated that such markers can be defined by various other means or that various other types of sensors can be used to detect overlap. Such sensors could include any of: proximity sensors, inductive, capacitive, magnetic and photoelectric sensors or any sensors suitable for detecting a marker position or degree of overlap between solar cell strip sections. In some embodiments, one or more markers can be defined as physical protrusions or recesses, the location of which can be readily determined optically, by use of a laser or any suitable means.

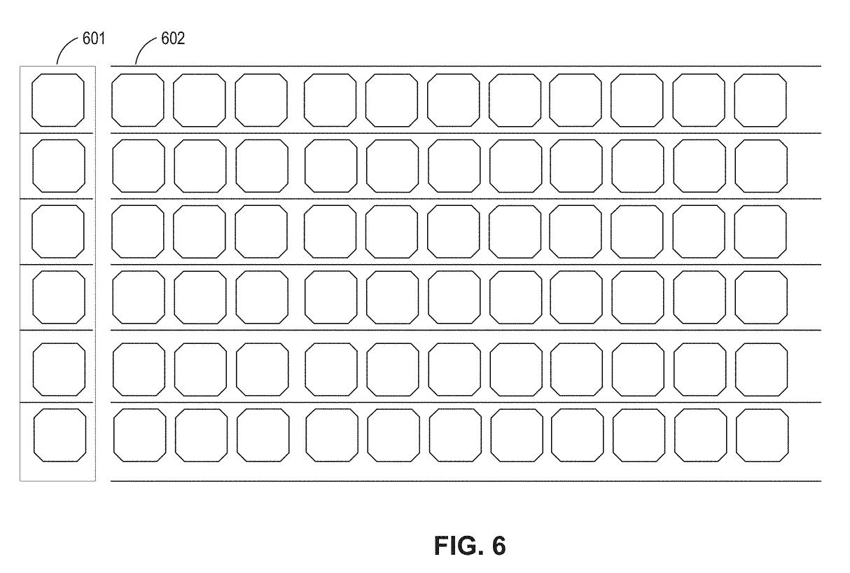

In step 401, solar cells which are placed in a coin stack can be lifted by a robotic arm or can be fed directly from a stack into a conveyor. Referring to FIG. 6, solar cells may be loaded from coin stack 601 on conveyor 602. FIG. 6 shows 6 coin stacks and 11 cells on each conveyor 602 that go through the process to form a complete panel. While FIGS. 6 and 8-10 depict an embodiment with six conveyors, it is appreciated that a single conveyor or any number of conveyors can be used.

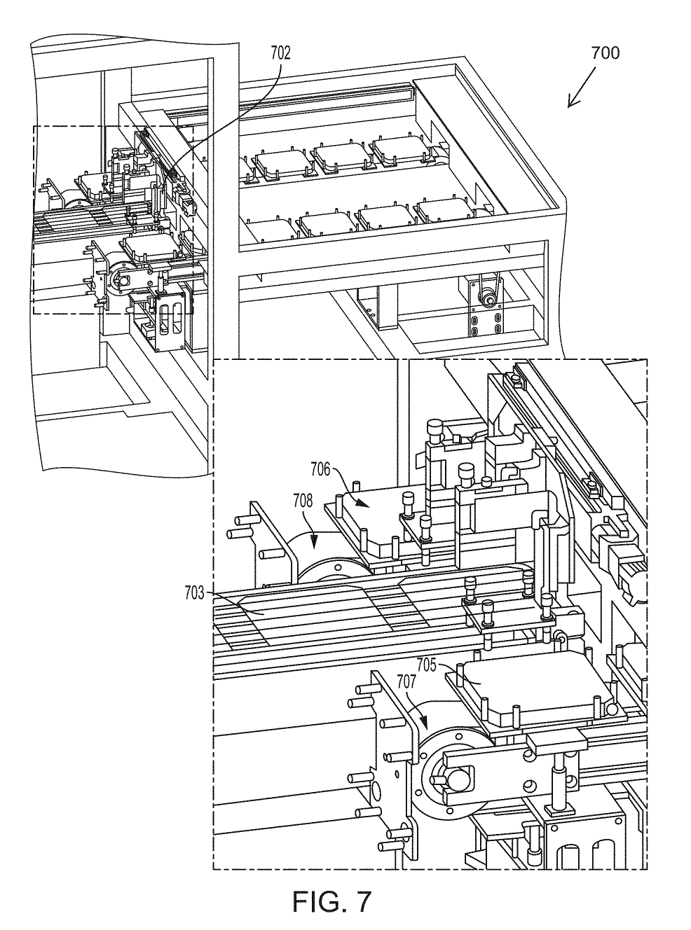

FIG. 7 shows loading station 700 where several coin stacks are placed on crawler wheels 707 and 708. A series of coins stacks on each wheel may form a queue. Robotic arm 702 can lift solar cells from each coin stack and place them on conveyor 703 (shown in FIG. 7B). When all cells from one coin stack are processed, the crawler wheel (707 and/or 708) that moves the coins stacks brings the next coin stack forward for processing. Empty coin stacks can rotate from underneath crawler wheels 707 and/or 708 and return to the beginning of the queue.

FIG. 7 shows seven coin stacks on each side of loading station 700. However, other variations for the number of coin stacks on each crawler wheel and the number of crawler wheels are also possible. There are two crawler wheels 707 and 708 each carrying four coin stacks. Each coin stack may contain a number of cells, for example, in one embodiment each coin stack contains 100 cells. An operator can load the cells in the coins stacks that are mounted on crawler wheels 707 and 708. Robotic arm 702 can lift and place the cells on conveyor 703 that transports the cells to a laser scribing module. As shown in FIG. 7, coin stacks are mounted on top of rotating crawler wheels 707 and 708 such that when cells from two coin stacks 705 and 706 are loaded on conveyor 703, the coin stack is moved back to the queue in loading station 700 via crawler wheels 707 and/or 708.

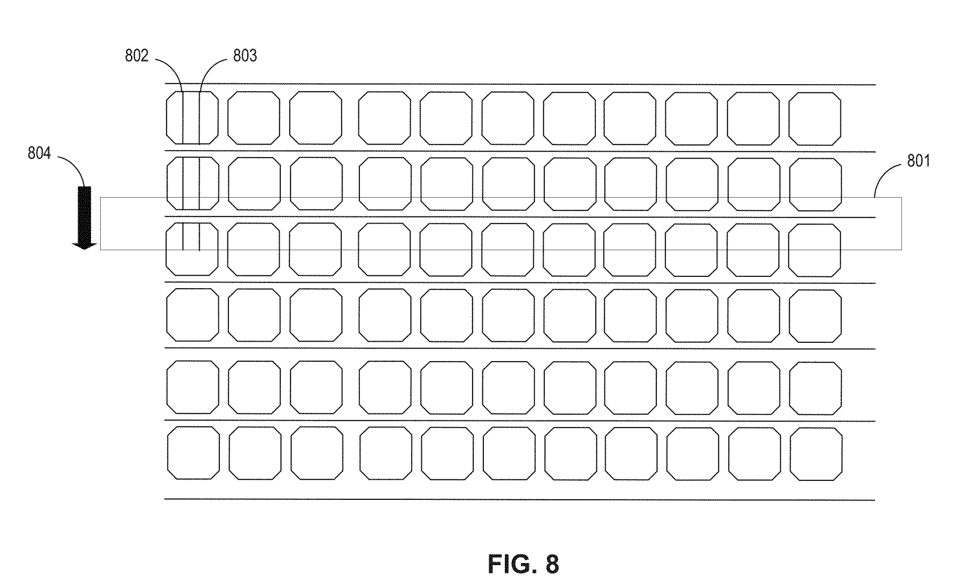

In step 402, each solar cell is divided into two or more strips that are used to form the “shingled” cells. In some embodiments, the cells may be divided by scribing the cells. Systems and methods for scribing photovoltaic structures are described in U.S. patent application Ser. No. 14/804,306, Attorney Docket Number P103-5NUS, entitled “SYSTEMS AND METHODS FOR SCRIBING PHOTOVOLTAIC STRUCTURES,” filed Jul. 20, 2015, the disclosure of which is incorporated herein by reference in its entirety for all purposes. FIG. 8 shows one method of dividing the cells that involves laser scribing the cells. Laser scribing module 801 positioned over the cells moves (in direction 804) to scribe all the cells. Lines 802 and 803 show the direction in which the laser module scribes the cells. These lines may correspond to blank space 105 in FIG. 1D. As stated above, other methods may be used for dividing the cells into smaller cells. The direction of laser scribe may be along the length of the conveyor or along its width.

FIG. 8 shows an embodiment with scribe lines 802, 803 along the width of each conveyor.

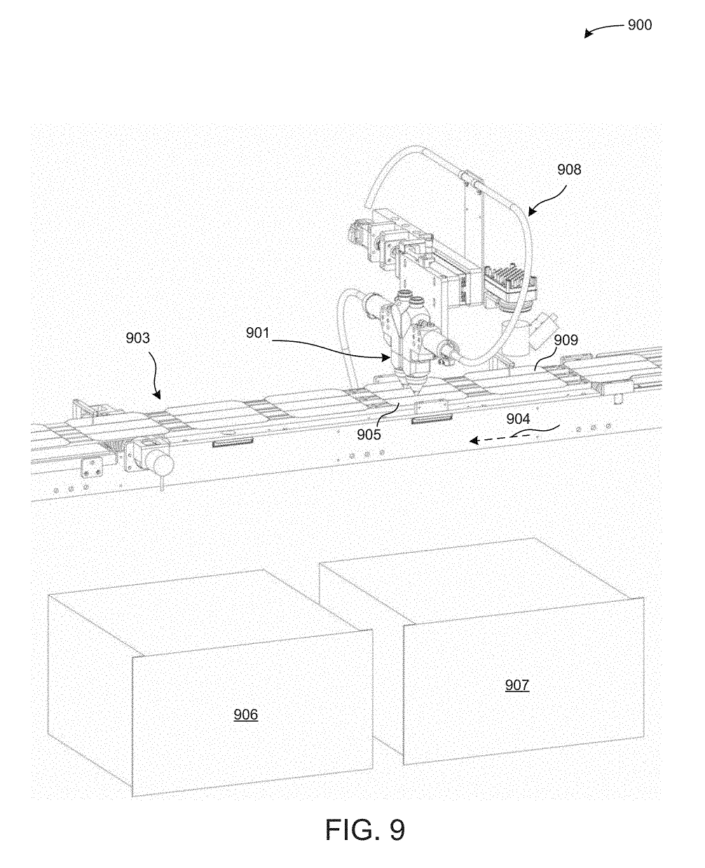

FIG. 9 shows another embodiment where cells are placed on a conveyor of an automated solar panel manufacturing system. This embodiment may be at the next stage after automatically loading cells from coin stacks as described with respect to FIG. 7. As shown in FIG. 9, the cells can be moved by conveyor 903 in direction 904 and a laser scribing module 901 can scribe the cells at predetermined locations similar to lines 802 and 803 in FIG. 8. In some embodiments, laser scribing module 901 may include or be coupled to laser generators 906 and 907, which generate the lasers used to scribe the cells. In some embodiments, before cells are transported via conveyor 903 to the location where laser scribing module 901 is positioned, the cells may pass through verification module 908 that verifies position by an image capture. While in this embodiment, the wafer moves along a conveyer while scribed, it is appreciated that in other embodiments, the wafer can remain in place while the scribing module moves the laser.

As described above, the busbars may be connected to each other in a shingled string by soldering each busbar to the other. However, one technical advantage in connecting the busbars via a conductive paste is that it allows the string of cells to be more flexible. Solar panels go through “thermal cycling” during a 24-hour period as the temperature changes.

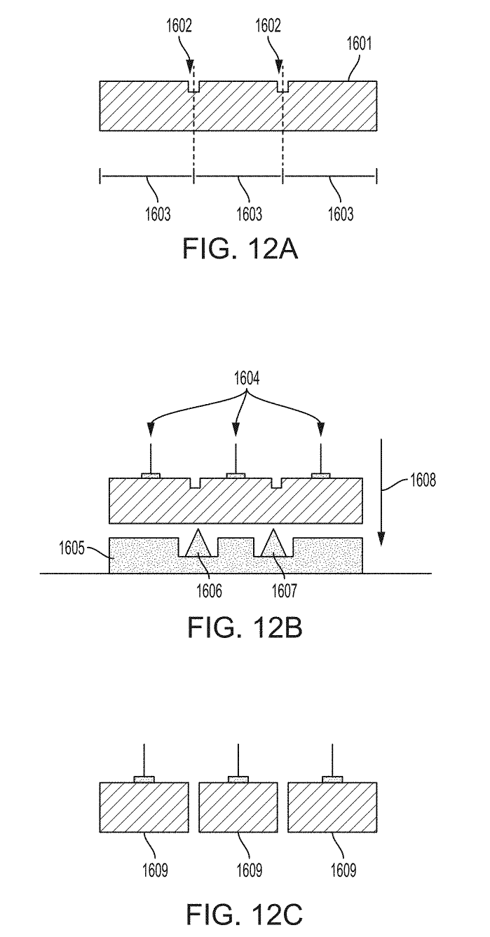

In step 403, scribed cells are placed on a cleaving station to be cleaved. Systems and methods for cleaving photovoltaic structures are described in U.S. patent application Ser. No. 14/826,129, Attorney Docket Number P103-3NUS, entitled “PHOTOVOLTAIC STRUCTURE CLEAVING SYSTEM,” filed Aug. 13, 2015, the disclosure of which is incorporated herein by reference in its entirety for all purposes. In some embodiments, after application of conductive paste (described above), the cells can be picked up by a robotic arm that lifts the cells via a vacuum that may be integrated into the robotic arm, and can hold the cell with a vacuum while transferring it to the cleave apparatus. As cell rows are placed on the cleaving apparatus, pressure may be applied to cleave and a vacuum may turned on to hold cleaved shingles in place. FIG. 12A shows one cell 1601 that is laser scribed. Cell 1601 may be divided by scribes 1602 into three even portions 1603 as described above. FIG. 12B shows that cell 1601 may be lifted using vacuum heads 1604 and placed on cleaving station 1605 having wedges 1606 and 1607. Cell may then be pushed downward in direction 1608 and divided into three smaller cells 1609 as shown in FIG. 12C.

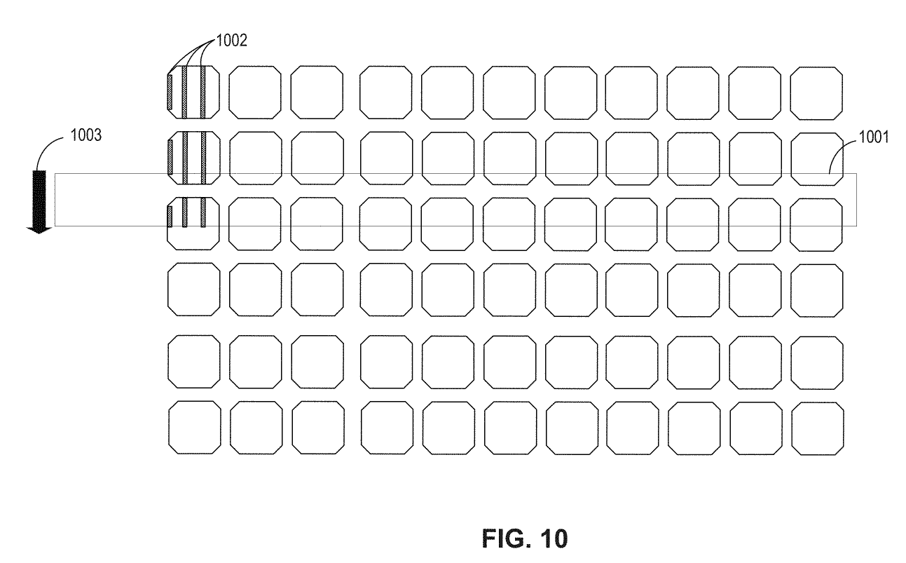

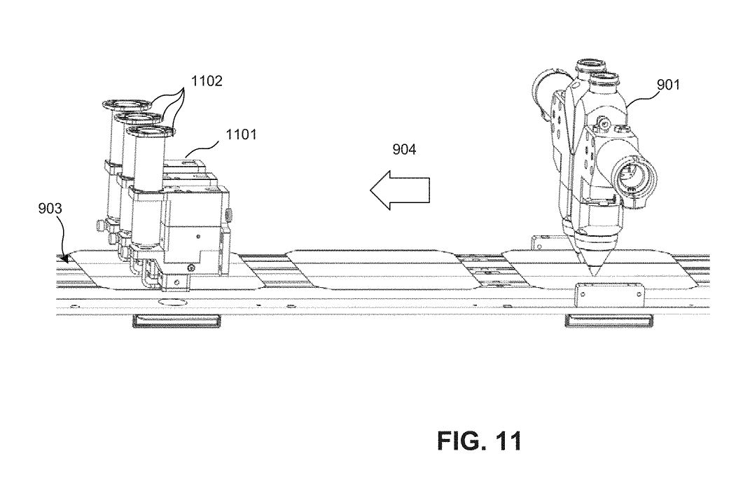

In step 404, conductive adhesive paste is applied on scribed cells. Systems and methods for applying conductive adhesive paste on photovoltaic structures are described in U.S. patent application Ser. No. 14/866,806, entitled “METHODS AND SYSTEMS FOR PRECISION APPLICATION OF CONDUCTIVE ADHESIVE PASTE ON PHOTOVOLTAIC STRUCTURES,” filed Sep. 25, 2015, the disclosure of which is incorporated herein by reference in its entirety for all purposes. FIG. 10 shows application of conductive paste on one column, according to one embodiment. Paste dispensing module 1001 can move over a string of cells and dispense conductive paste on the cells. FIG. 11 shows the application of the paste via paste dispensing module 1101. Paste dispensing module 1101 may be in the form of one or more syringes 1102 or a jetting unit. The paste may be applied as the cell is being moved by conveyor 903, or while conveyor 903 is stationary.

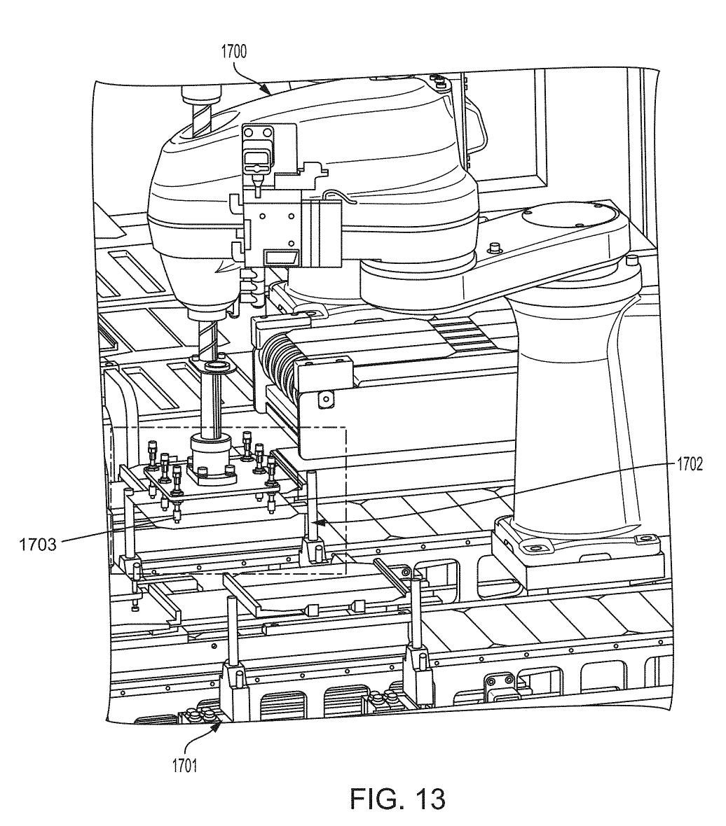

FIG. 13 shows an exemplary embodiment where robotic arm 1700 loads the cells on loading mechanisms 1701 and 1702. The lifting mechanism of robotic arm 1700 can include six vacuum heads 1703 that hold the cells during transport. Loading mechanisms 1701 and 1702 may also act as a buffer where the cells may be accumulated and ready to be transported to the cleaving station via robotic arm 1700.

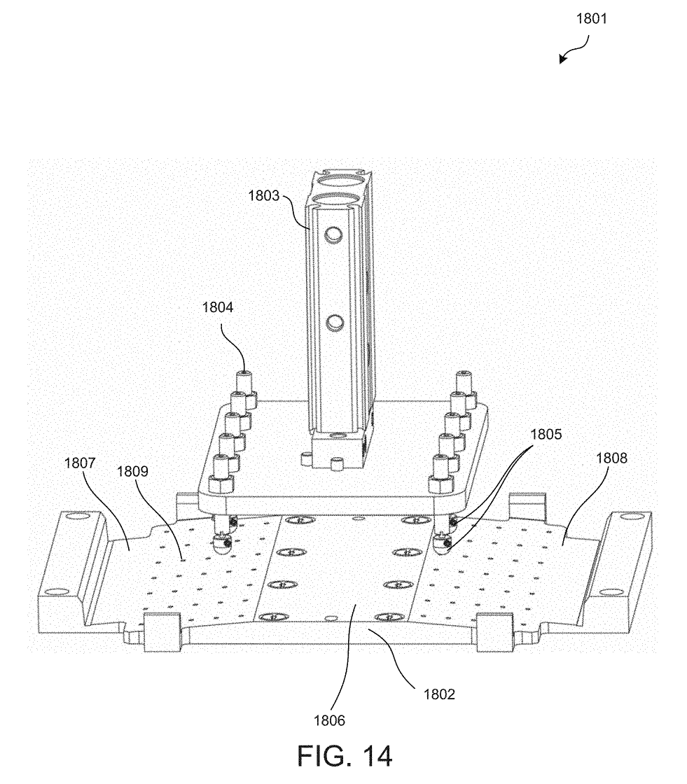

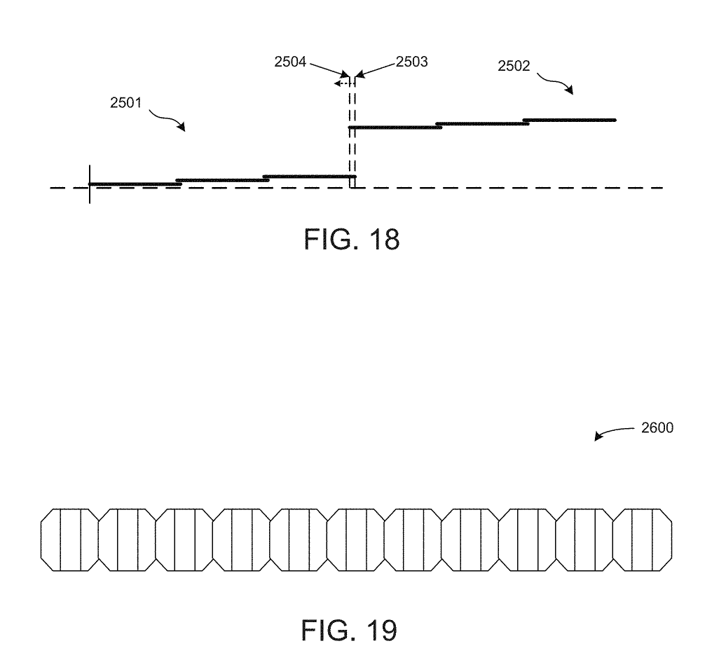

FIG. 14 shows cleaving apparatus 1801 according to one embodiment. Cleaving apparatus 1801 may have base 1802, cleaving actuator 1803, and spring plungers 1804 and cleave tips 1805. Base 1802 has a middle surface 1806 that is substantially flat and two side surfaces 1807 and 1808 that have an angle with respect to middle surface 1806. As shown in FIG. 18, two fulcrums edges are formed between middle surface 1806 and the side surfaces 1807 and 1808. Middle surface 1806 may support the middle portion of a cell, and each of side surfaces 1807 and 1808 may support the outer portions of a cell. When a cell is placed on base 1802, the scribed lines may be aligned on the two fulcrum edges between middle surface 1806 and side surfaces 1807 and 1808. Side surfaces 1807 and 1808 of base 1802 may have holes 1809 that can allow the passage of air from beneath base 1802 in an upward direction. When a cell is placed on base 1802, cleaving actuator 1803 can apply pressure on the cell toward base 1802, while the cell may also be subjected to simultaneous air pressure in the opposite direction from side surfaces 1807 and 1808. The downward pressure from cleaving actuator 1803 and cleave tips 1805 can break the cell along the scribed lines which may happen to be on the same position as the fulcrum edges. As a result, each cell can be divided into three smaller strips of solar cells as described previously. The air-pressure from the sides of base 1802 ensures that the outer pieces of the cell are positioned correctly on cleaving apparatus 1801 after cleaving. In one embodiment, middle portion 1806 of base 1802 directly underneath cleaving actuator 1803 may have a vacuum built into the surface of base 1802 that can hold the cell in place and prevent the cell from breaking before the application of the pressure by cleaving actuator 1803.

In one embodiment, cleave tip 1805 may be partially housed inside spring plunger 1804 and a spring can be placed inside spring plunger 1804 to absorb some of the pressure exerted by cleaving actuator 1803, which can prevents excessive pressure to the surface of the cell.

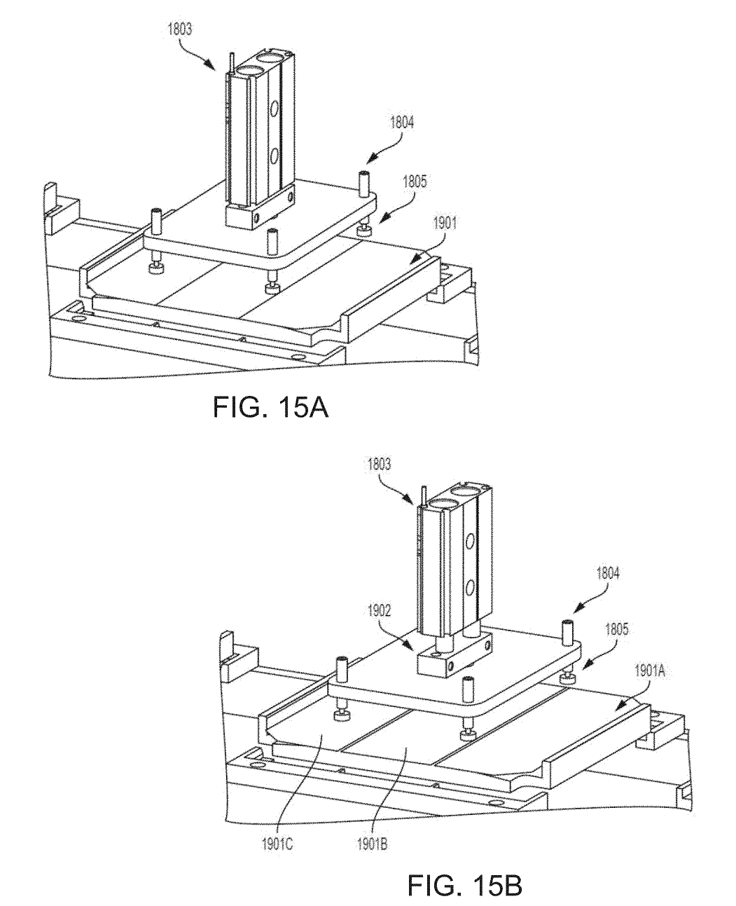

FIG. 15A shows cell 1901 that is placed on cleaving station 1801 before application of pressure by cleaving actuator 1803. FIG. 15B illustrates a cleaved cell that can be divided into three pieces 1901A, B, and C (i.e. three strips of solar cells). As shown in FIG. 15B, middle piece 1901B stays on the middle of base 1802, while the other two pieces 1901A and C slide down the angled surface and are stopped by the side walls 1810 of cleaving apparatus 1801. As shown in FIG. 15A, cleave tips 1805 apply pressure to the two outer pieces within a cell which causes breakage along the scribed lines of the cell. In optional step 405, after dividing one cell into three strips, the cells may be tested using a probe.

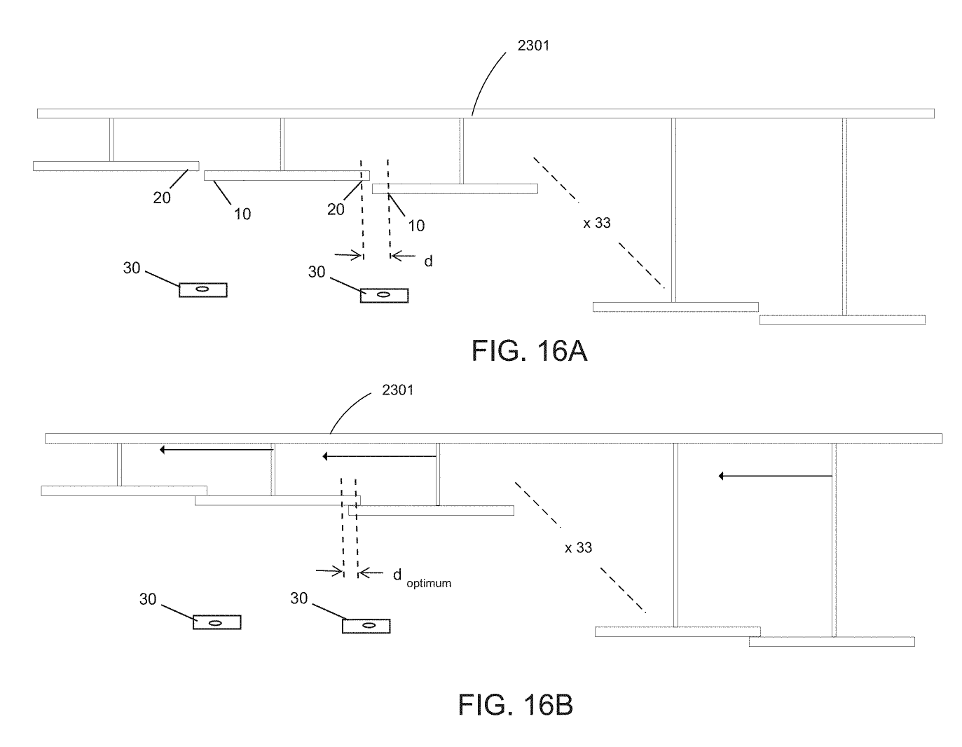

In step 406a, the strips are shingled. Systems and methods for shingling photovoltaic structures are described in U.S. patent application Ser. No. 14/866,776, Attorney Docket Number P103-4NUS, entitled “SYSTEMS AND METHODS FOR CASCADING PHOTOVOLTAIC STRUCTURES,” filed Sep. 25, 2015, the disclosure of which is incorporated herein by reference in its entirety for all purposes. In one embodiment, a vacuum mechanism may lift, shift and align the cells to form a shingle assembly. FIG. 16A shows vacuum mechanism 2301 lifting the cells with an offset. The degree of offset can be determined by sensor 30 by monitoring the distance between first marker 10 and second marker 20. FIG. 16B shows the shifting and aligning of the cells with vacuum mechanism 2301 until sensor 30 indicates that the monitored distance is optimum, or within an optimum range, that is indicated of a desired overlap within the shingle assembly. The sections of the shingled assembly can then be bonded through an annealing process, or any suitable process as would be understood by one of skill in the art.

In step 406b, an overlap distance of the shingled strips is determined. Typically, this includes determining a distance between a first marker of one strip and a feature (e.g. first or second marker) of an adjacent strip, the distance corresponding to the amount of overlap. Since the markers or features are disposed on a backside of the strips, this determination can be made by a sensor unit disposed under the backside during assembly. Typically, the markers are visual such that the sensor can utilize an optical detect to identify the markers and their respective locations. The sensor unit can include a processing unit having a memory with instructions recorded thereon to automatically determine the distance from the locations of the identified markers. This approach is particularly advantageous as it allows for improved alignment in an automated assembly process. This overlap determination can be used periodically, such as in a quality control check, or can be performed at high repetition rates, or iteratively to allow for dynamic real-time adjustment of the solar cell strips during assembly, such as in the optional subsequent step.

In step 406c, the solar cell strips of the assembly are adjusted in response to the detection or determination of the distance corresponding to overlap between shingled solar cell strips. This adjustment can be made periodically in response to an occasional overlap check or can be made in real-time in response to high-repetition or substantially continuous overlap determinations (e.g. performed along each overlap during assembly).

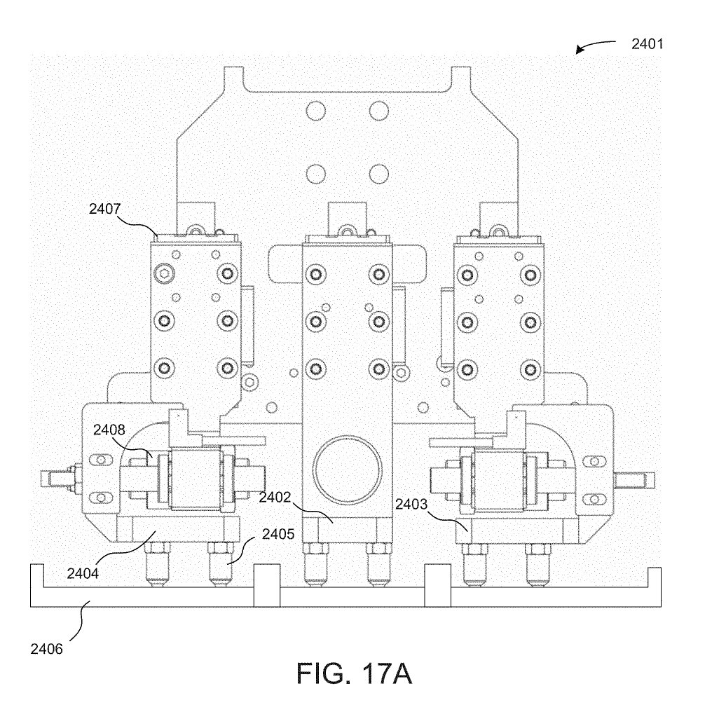

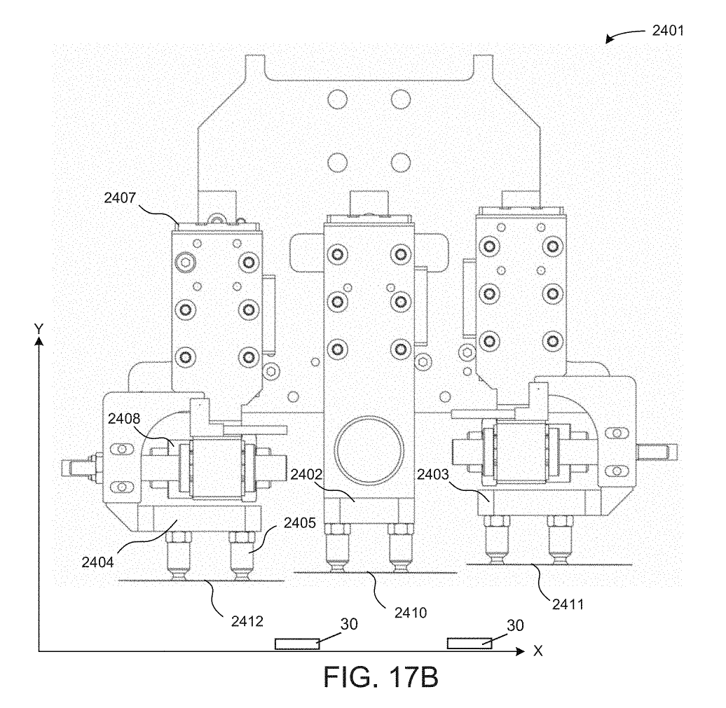

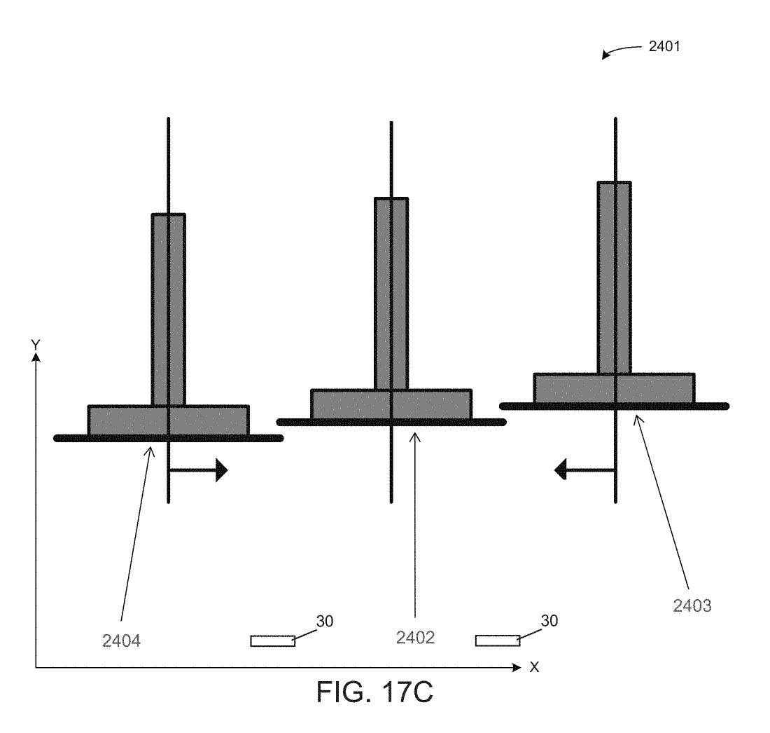

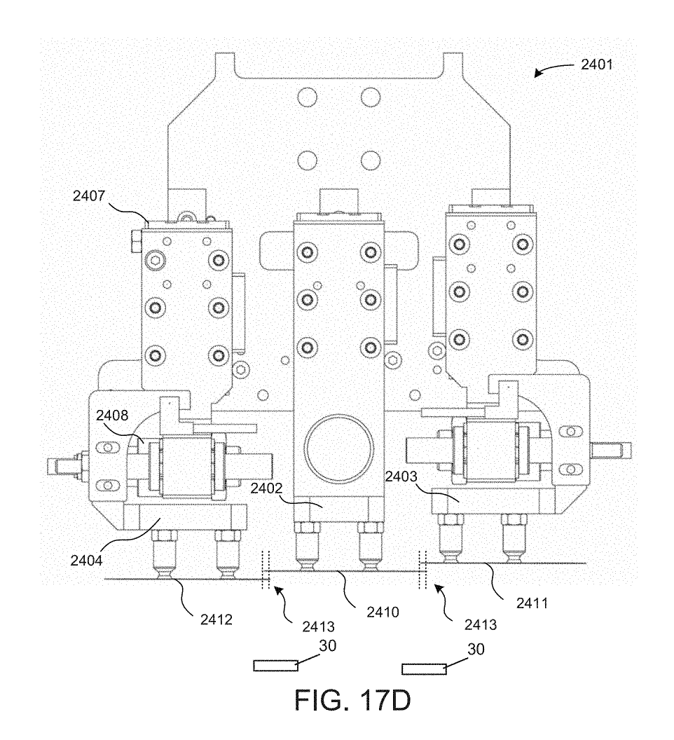

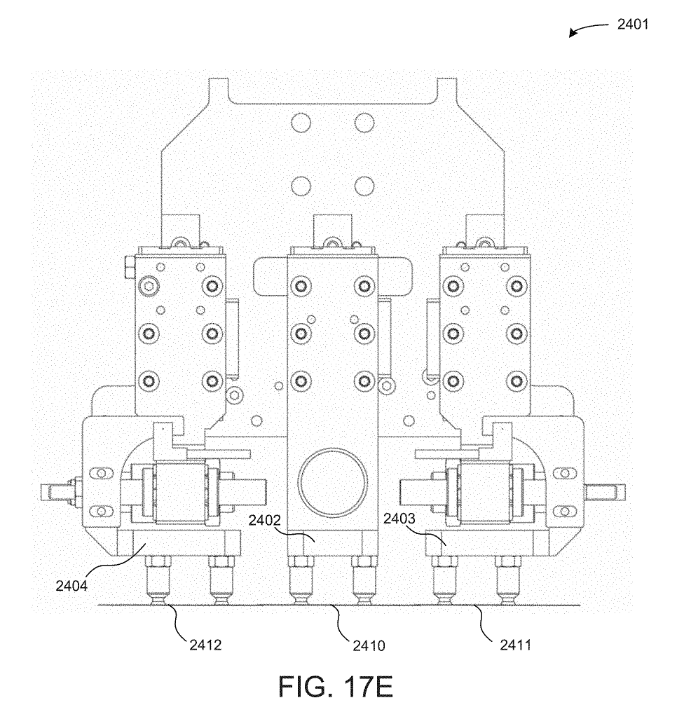

FIG. 17A shows shingling module 2401 that can lift, shift and align the cells to form a shingle assembly according to one embodiment. Shingling module 2401 may be a precision automated system that shingles the strips of solar cells. Shingling module 2401 includes center mechanical arm 2402, mechanical arm 2404 on the left side and mechanical arm 2403 on the right side. Each mechanical arm may have one or more suction cups 2405. Shingling module 2401 also may have table 2406 that houses the strips of solar cells. In some embodiments, each of the mechanical arms is capable of moving both in the vertical and horizontal direction. As shown in FIG. 17B, each mechanical arm can lift the strips via suction cups 2405 that apply a holding force to the surface of the strips of solar cells. Each of the mechanical arms can lift the strip it is holding (2410, 2411, and 2412) to a predetermined height, and as a result, the stepped formation shown in FIG. 17B is created. In the embodiment shown in FIG. 17C, mechanical arms 2403 and 2404 move toward mechanical arm 2402 by a predetermined distance until the strips overlap a desired or predetermined distance. In this embodiment, the desired degree of overlap is about 2 millimeters, which corresponds to the width of the busbar on each strip. It is appreciated that the desired degree of overlap may depend on the particular configuration of the solar cell design. FIG. 17D shows another view of the strips while being lifted and overlapped in a shingled formation by moving mechanical arms 2403 and 2404 toward mechanical arm 2402 by a predetermined distance to obtain desired overlap 2413. The stepped formation shown in FIG. 17D may be formed on a location, with respect to the flat surface under the mechanical arms, such that when the shingled assembly is placed on the flat surface, the strip of solar cell on the left overlaps the shingle assembly that is already placed on the flat surface. In some embodiments, sensor 30 can be disposed within a recess or a window of the flat surface.

In the embodiment shown in FIG. 17E, every three strips of solar cells are formed into a shingle assembly and placed on a flat surface. This process is repeated to form a longer string of shingled cells. Stated differently, each shingle assembly which includes three strips of solar cells can be placed on another shingle assembly which may be on the flat surface. This results in a longer string of shingled solar cells for every cycle of operation of shingling module 2401.

FIG. 18 shows one shingle assembly 2501 that is placed on a flat surface. Another shingle assembly 2502 can also be placed on top of shingle assembly 2501 to form a longer string. Shingle assembly 2502 also overlaps the shingle assembly 2501 by an amount equal to the distance between points 2503 and 2504, which may be 2 mm in some embodiments.

In one embodiment, shingling module 2401 may have more mechanical arms such that an entire string may be formed during one cycle. In this embodiment, the mechanical arms lift the strips, create a stepped formation while the strips are lifted, move the strips to achieve a proper amount of overlap and place the strips to form a string of shingled cells. In another embodiment, the process may be divided into multiple sub-processes such that two or more strips are lifted and aligned to form a partial shingled string and the partial string is then lifted and aligned with another partial string to form a complete shingled string similar to the string 2600 shown in FIG. 19.

Shingling module 2401 may control the movement of the mechanical arms in a number of ways. In one embodiment, the movement of the mechanical arms in horizontal and vertical directions may be controlled by a firmware that controls the movement of each mechanical arm from a first three-dimensional coordinate to a second three-dimensional coordinate. In another embodiment, shingling module 2401 may be retrofitted with a vision system that measures the distance of each mechanical arm with respect to another mechanical arm, or any other reference point, and provides near real-time feedback to a control module that directs the movement of the mechanical arm. In another embodiment, any combination of the above-noted methods may be used, in addition to other methods of movement control, to direct the movement of the mechanical arms and achieve the desired level of precision.

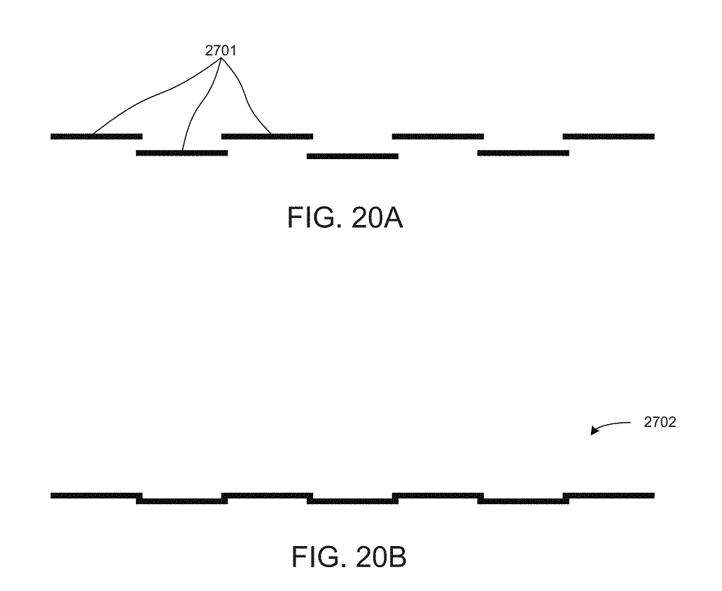

In one embodiment, shingled module 2401 may shingle the strips as shown in FIG. 27B. FIG. 20B shows a string where instead of a continuous stepped formation, the strips overlap on two edges of one surface. This configuration may need a different metal grid pattern where each strip has two busbars on one side to accommodate the particular configuration shown in FIG. 20B. As shown in FIG. 20A, shingling module 2401 arranges the strips such that each strip overlaps two other strips on one side.

One problem solved by shingling module 2401, and a technical advantage that results from the operation of shingling module 2401, is the level of precision that shingling module can achieve in overlapping the strips. Shingling module 2401 overlaps the strips by the proper distance so that the busbars of each strip of solar cell are substantially aligned. Performing this process manually is prone to human error and the level of precision required in overlapping the busbars for a string to properly operate cannot be readily be achieved in a manual process. Thus, including the first marker within the backside design allows for a dependable and cost-effective means of improving alignment of adjacent sections during the shingling process. Further, such an approach reduces dependency on edge ring monitoring and improved resolution in overlap data as compared to previous approaches.

Once a complete string is assembled, a conductive tab can be attached to one end of the string and can provide an electrical contact on the opposite side of the string. Given that each strip of cell has one busbar on each side, when a series of strips are shingled, the busbars at the far ends of the string are positioned on the opposite side of the string with respect to each other. The tab allows one of the busbars at one end of the string to be electrically accessible from the other side of the string.

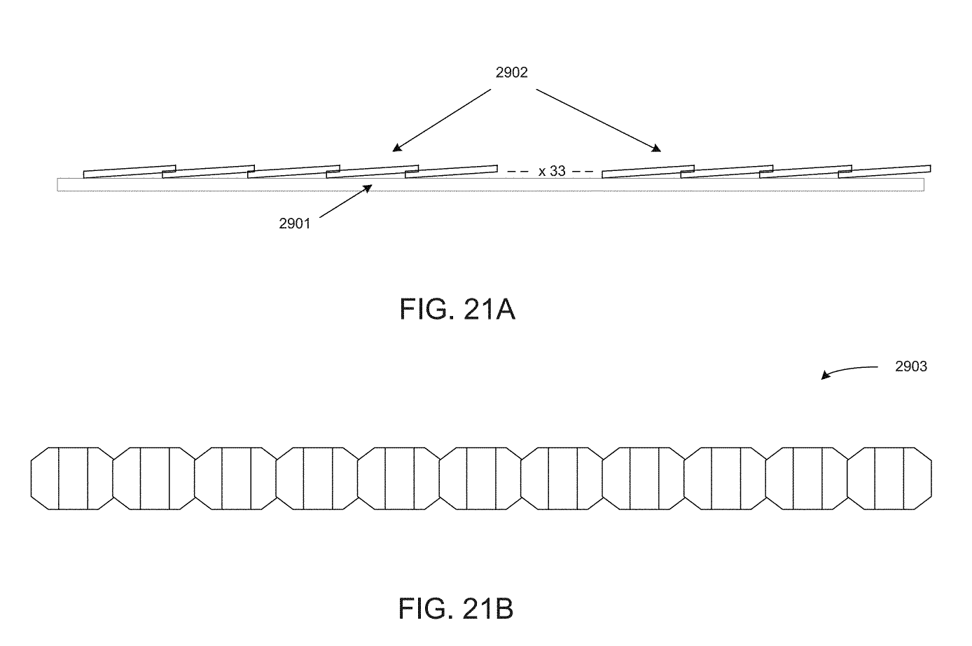

In step 407, the shingle assembly is annealed. In one embodiment, shown in FIG. 21A, string 2902 is placed on heated plate 2901 that is substantially flat and heated up to 160° Celsius. The heat cures the conductive paste that binds the busbars between two strips of solar cells, and results in annealed string 2902 shown in FIG. 21B. This annealing process may be repeated for each shingle string. In another embodiment, the string is annealed by a targeted annealing module that applies heat to selective areas of the string of shingled cells. For example, the string of shingled cells may be placed on an annealing platform and a number of heat-tearing bars may apply heat to the areas of the string where two strips overlap. Systems and methods for targeted annealing of photovoltaic structures are described in U.S. patent application Ser. No. 14/866,817, entitled “SYSTEMS AND METHODS FOR TARGETED ANNEALING OF PHOTOVOLTAIC STRUCTURES,” filed Sep. 25, 2015, the disclosure of which is incorporated herein by reference in its entirety for all purposes.

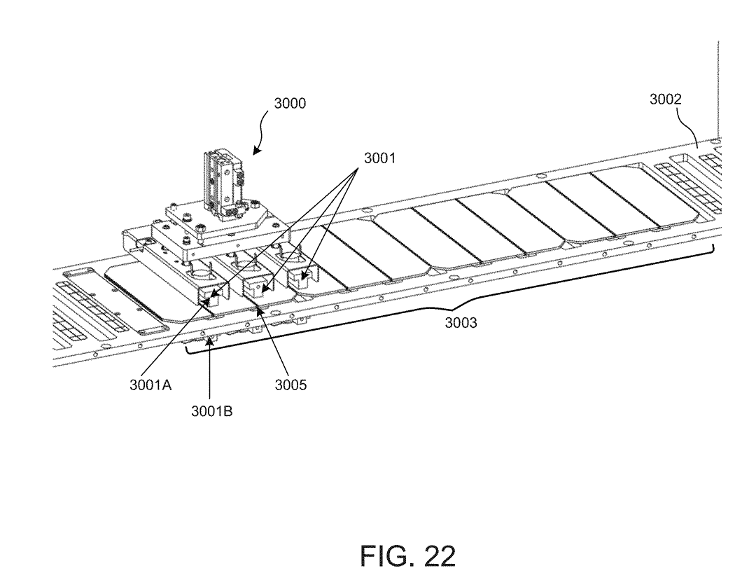

FIG. 22 show targeted annealing module 3000, according to one embodiment, that includes heat-treating bars 3001 having top bars 3001A and bottom bars 3001B (shown more clearly in FIG. 30B), and surface 3002 that is substantially flat. String 3003 can be placed on surface 3002. Surface 3002 may have a series of openings 3004 that allow heat-treating bars 3001 to contact the string from under surface 3002. Heat-treating bars 3001 can be positioned such that as they approach the string, they apply heat to both sides of the string around the area where strips overlap. One such area is shown as area 3005. In some embodiments, heat-treating bars can cure the overlapping areas of the strips up to 160° Celsius.

In one embodiment, the string of shingled cell can move in a horizontal direction on surface 3002 to align the overlapped areas on openings 3004. After the alignment is complete, heat-treating bars 3001 can establish contact with the string to cure the conductive paste that bind the strips. In another embodiment, targeted annealing module 3000 may have more heat-treating bars such that one set of heat-treating bars is dedicated to each overlapped area of the string. In this embodiment, the annealing process for the entire string can be performed in one cycle. The heat causes the paste in between busbars of the strips of solar cells to cure. In some embodiments, the conductive paste may be in a form of a resin that includes a number of conductive particles. The conductive particles may be coated with a protection layer that evaporates when the paste is thermally cured and thereby results in electrical conductivity between the conductive particles that are suspended inside the resin.

One problem solved by targeted annealing module 3000, and a technical advantage that results, is that it prevents damage to the photovoltaic structure of the solar cells because of heat. The unique design of the targeted annealing module 3000 allows the targeted application of heat only to the areas of the solar cells that need to be cured. Furthermore, the temperature of the heat-treating bars and the amount of time that the heat-treating bars touch the surface of the solar cells can be calibrated to achieve the optimum level of curing.

In step 408, the shingle rows are picked and placed on a frame for lamination. In an embodiment, the strings are placed on a backsheet. The strings are then electrically connected together and a glass cover can be placed on top of the strings. The backsheet and the glass cover are then placed in a frame. Systems and methods for placement of backsheet on PV modules are described in U.S. patent application Ser. No. 14/877,870, Attorney Docket Number P103-8NUS, entitled “SYSTEMS, AND METHOD FOR PRECISION AUTOMATED PLACEMENT OF BACKSHEET ON PV MODULES,” filed Oct. 7, 2015, the disclosure of which is incorporated herein by reference in its entirety for all purposes.

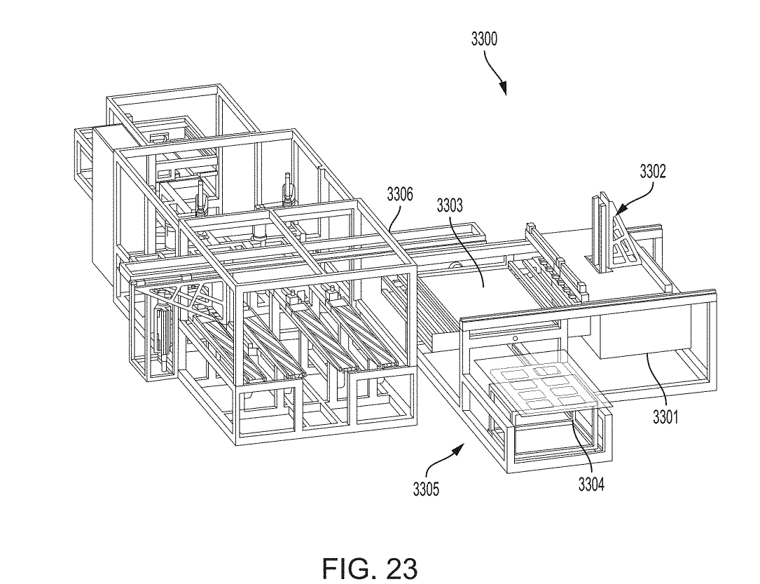

FIG. 23 shows automated layup tool 3300 according to one embodiment. Automated layup tool 3300 may include backsheet stack 3301, backsheet pick and place module 3302, vacuum table 3303, glass shuttle and lift 3305 with carry glass cover 3304, string pick and place module 3306, paste dispense module 3307, support fixture 3308, and heating module 3309. It will be understood by those skilled in the art, that various operations of layup tool 3300 described above can be altered and modified depending on other designs for the string. Therefore, it will be understood that the order of steps in which the operation of the various tools described herein are not limiting and that the alignment concepts described herein could be applied to various other layup and assembly tools.

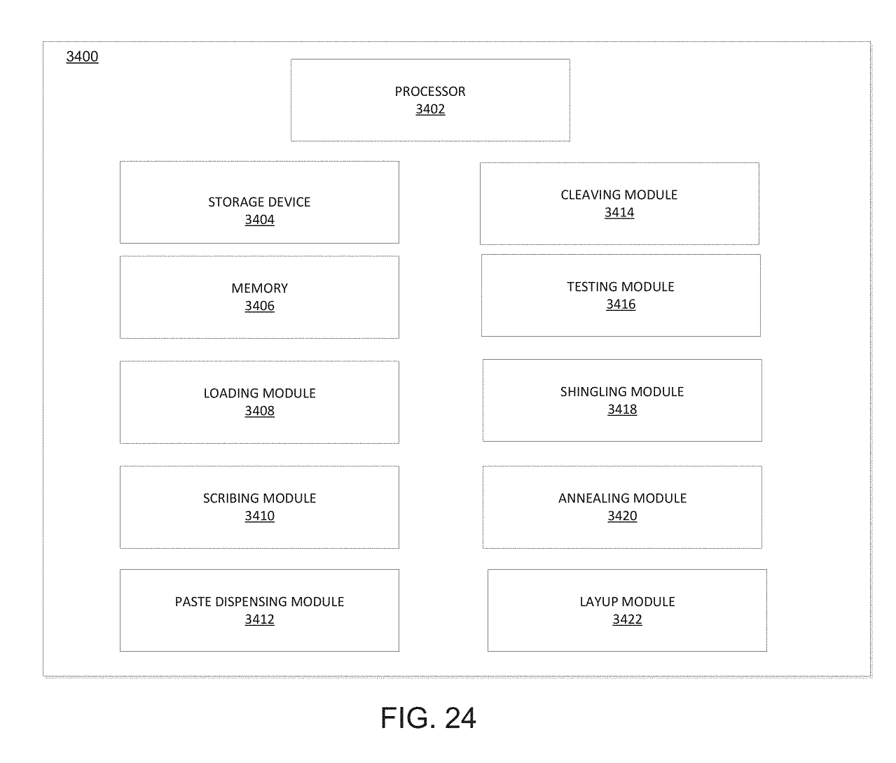

FIG. 24 shows control system 3400 that can facilitate assembly of a solar panel. Control system 3400 can include multiple modules which may communicate with one another via a wired or wireless communication channel. Control system 3400 may be realized using one or more integrated circuits, and may include fewer or more modules than those shown in FIG. 34. Further, control system 3400 may be integrated in a computer system, or realized as a separate device which is capable of communicating with other computer systems and/or devices, such as the devices of systems 3200 and 3300.

Control system 3400 can include processor 3402, storage device 3404, and memory 3406. Memory 3406 can include a volatile memory (e.g., RAM) that serves as a managed memory, and can be used to store one or more memory pools. In some embodiments, storage device 3406 can store an operating system, and instructions for monitoring and controlling the assembly of a solar panel, such as according to any of the processes and methods described herein.

Control system 3400 can include loading module 3408, which controls operation of one or more devices associated with loading solar cells onto a conveyor. Such devices, for example, can include robotic arms and/or solenoids for applying suction to solar cells and motors for actuating aspects of solar cell loading. Control system 3400 can further include scribing module 3410, which controls operation of one or more devices associated with scribing solar cells, which can include scribing modules 801, 901, and 3203 described above, and the devices and components described with respect to these modules. Scribing module 3410 can be accompanied by a vision system (e.g., one or more cameras) that can capture images of cells in association with the laser scribing, which can also be used to determine the distance between markers during overlapping or shingling of solar cell sections. It is understood that other types of sensor systems can be used in conjunction with scribing module 3410.

Control system 3400 can include paste dispensing module 3412, which controls operation of one or more devices associated with dispensing conductive paste on solar cells, which can include modules 1001, 1101, 3304 described above and the devices and components described with respect to these modules. Control system 3400 can further include cleaving module 3414, which controls operation of one or more devices associated with cleaving solar cells, which can include cleaving apparatus 1801, and the devices and components described with respect to apparatus 1801. Such devices, for example, can include cleaving actuators, spring plungers, cleave tips, and lift mechanisms described above with respect to cleaving apparatus 1801. Cleaving module 3414 can be accompanied by a vision system (e.g., one or more cameras) that can capture images of cells in association with the cleaving, which can also be used to measure the distance between markers during shingling. However, it is understood other types of sensor systems can be used in conjunction with cleaving module 3414.

Control system 3400 can include testing module 3416, which controls operation of one or more devices associated with electrical testing of solar cells, including testing unit 2200 described above, and the devices and components described with respect to testing unit 2200.

Control system 3400 can include shingling module 3418, which controls operation of one or more devices associated with shingling solar cells into strings, which can include vacuum mechanism 2301, shingling module 2401, and the devices and components described above with respect to mechanism 2301 and module 2401. Such devices, for example, can include mechanical arms with one or more suction cups to hold solar cells in place and actuators to position the mechanical arms holding solar cells in desired positions to form strings. Shingling module 3418 can be accompanied by a vision system (e.g., one or more cameras) that can capture images of cells in association with the shingling, which can also determine the distance between solar cell sections. However, it is appreciated that other types of sensor systems can be used in conjunction with shingling module 3418.

Control system 3400 can include annealing module 3420, which controls operation of one or more devices associated with annealing strings, which can include annealing module 3000 and devices and components described above with respect to module 3000.

Control system 3400 can include layup module 3422, which controls operation of one or more devices associated with placing the string on a backsheet, electrically connecting the strings, and placing a glass cover on top of the strings, which can include automated layup tool 3300. Such devices may include backsheet pick and place module 3302, vacuum table 3303, glass shuttle and lift 3305, string pick and place module 3306, paste dispense module 3307, support fixture 3308, and heating module 3309.

In some embodiments of the system, the desired overlap of the second solar cell section with the first solar cell is within a range of 0.5 mm to 10 mm, typically between 1 mm to 5 mm, more typically, about two millimeters. The distance between markers corresponding to the desired overlap depends on the placement of the first and second markers on the respective solar cell sections.

Other variations are within the spirit of the present invention. Thus, while the invention is susceptible to various modifications and alternative constructions, certain illustrated embodiments thereof are shown in the drawings and have been described above in detail. It should be understood, however, that there is no intention to limit the invention to the specific form or forms disclosed, but on the contrary, the intention is to cover all modifications, alternative constructions, and equivalents falling within the spirit and scope of the invention, as defined in the appended claims.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. The term “connected” is to be construed as partly or wholly contained within, attached to, or joined together, even if there is something intervening. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate embodiments of the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

What is claimed is:

1. A photovoltaic structure comprising:
a base layer;
a first and second quantum tunneling barrier (QTB) layer deposited on opposing surfaces of the base layer;
an amorphous silicon emitter layer;
an amorphous silicon surface field layer; and
at least one metallic grid on a back-side of the photovoltaic structure that includes a first marker positioned to facilitate alignment of the photovoltaic structure with an adjacent overlapping photovoltaic structure during assembly of a photovoltaic string.

2. The photovoltaic structure of claim 1, wherein the first marker comprises a feature that is identifiable by a sensor and/or a user.

3. The photovoltaic structure of claim 2, wherein the sensor is an optical or photo-sensor.

4. The photovoltaic structure of claim 2, wherein the first marker comprises a modification of a standard pattern of the at least one metallic grid.

5. The photovoltaic structure of claim 4, wherein the first marker comprises a deviation in a length of a row of the standard grid pattern.

6. The photovoltaic structure of claim 4, wherein the first marker comprises a an extension of an edge busbar in a portion of the grid pattern that extends laterally between adjacent fingers of the grid pattern.

7. The photovoltaic structure of claim 1, wherein the first marker comprises at least two markers near opposite ends of an edge that is overlapped with the adjacent structure.

8. The photovoltaic structure of claim 1, wherein the first marker is aligned with a second marker in the adjacent photovoltaic structure within the photovoltaic string along a direction of overlap.

9. The photovoltaic structure of claim 8, wherein the second marker is a contact pad in an existing back-side design of the adjacent photovoltaic structure.

10. A photovoltaic structure, the structure comprising:
a front side having a solar energy receiving surface;
a back side having a metal grid for harvesting electrical energy from the photovoltaic structure upon receiving solar energy on the front side; and
a first marker disposed on the back side to facilitate alignment of the photovoltaic structure with an adjacent overlapping photovoltaic structure during assembly of a string of interconnected photovoltaic structures.

11. The photovoltaic structure of claim 10, wherein the first marker is defined within the metal grid pattern.

12. The photovoltaic structure of claim 11, wherein the first marker is disposed within the grid pattern so as to be adjacent and aligned with a second marker in the adjacent photovoltaic structure along a direction of overlap.

13. A system for forming a photovoltaic string having overlapping photovoltaic sections, the system comprising:
a shingling module for positioning a plurality of photovoltaic structures relative each other, each of the plurality of photovoltaic structures being as in claim 10, wherein the shingling module has a plurality of support elements adapted to support each of the photovoltaic structures; and
a sensor unit adapted and positioned to identify the first marker of each of the plurality of photovoltaic structures and configured to determine a distance between the first marker of a respective photovoltaic panel and a second marker of an adjacent overlapping photovoltaic structure.

14. The system of claim 13, wherein the first marker is defined within the metal grid pattern.

15. The system of claim 13 further comprising:
a control unit operatively coupled with at least some of the plurality of support elements and the sensor unit, wherein the control unit is configured to adjust a position of the plurality of photovoltaic structures via movement of the support elements in response to a determination of the distance between the first and second markers in adjacent photovoltaic structures, the distance corresponding to an overlap of the adjacent photovoltaic structures.

16. A method for aligning a plurality of photovoltaic structures within a string of interconnected photovoltaic structures, the method comprising:
supporting the plurality of photovoltaic structures such that the structures are independently positionable relative each other, each of the plurality of photovoltaic structures having a front side adapted for receiving solar energy and a back side having a metal grid for harvesting electrical energy produced by the photovoltaic structure;
positioning one or more photovoltaic structures of the plurality so that at least a first photovoltaic structure has an overlap with a second photovoltaic structure of the plurality;
detecting a first marker in a back-side of the first photovoltaic structure; and
determining whether an overlap between the first photovoltaic structure and the adjacent second photovoltaic structure is within a desired range based on a position of the first marker relative a position of a second marker in the second photovoltaic structure.

17. The method of claim 16 wherein the first marker is a modification of a standard pattern of the metal grid that is identifiable by one or more sensors.

18. The method of claim 16 wherein the second marker is unique feature and/or an existing feature in a back-side of the second photovoltaic structure.

19. The method of claim 16 wherein determining whether the overlap is within the desired range comprises determining a distance between the first marker and the second marker.

20. The method of claim 16 further comprising:
repositioning at least one of the photovoltaic structures of the plurality in response to a determination that the overlap is outside of the desired range.
